(19) United States
(12) Patent Application Publication
(10) Pub. No.: US 2025/0221110 A1
(43) Pub. Date: Jul. 3, 2025

(54) LIGHT EMITTING ELEMENT, DISPLAY DEVICE INCLUDING THE SAME, AND METHOD OF FABRICATING LIGHT EMITTING ELEMENT

(71) Applicant: Samsung Display Co., LTD., Yongin-si (KR)

(72) Inventors: In Hyuk KIM, Yongin-si (KR); Ji Hyun HAM, Yongin-si (KR); Yun Ha RYU, Yongin-si (KR); Young Chul SIM, Yongin-si (KR)

(73) Assignee: Samsung Display Co., LTD., Yongin-si (KR)

(21) Appl. No.: 18/810,856

(22) Filed: Aug. 21, 2024

(30) Foreign Application Priority Data
Dec. 27, 2023 (KR) 10-2023-0192189

(51) Int. Cl. H01L 33/46; H01L 25/075; H01L 33/00

(52) U.S. Cl. CPC H10H 20/841; H01L 25/0753; H10H 20/01; H10H 20/034

(57) ABSTRACT

A light emitting element according to an embodiment includes semiconductor layers including a first semiconductor layer, a light emitting layer, and a second semiconductor layer. The light emitting element further includes a multi-insulating film including a first insulating film, a second insulating film, and a third insulating film sequentially surrounding side surfaces of the semiconductor layers, a low refractive index film surrounding the multi-insulating film and having a thickness greater than a thickness of the multi-insulating film, and a reflective film surrounding the low refractive index film and including metal.

### CROSS-REFERENCE TO RELATED APPLICATION(S)

This application claims priority to and benefits of Korean Patent Application No. 10-2023-0192189 under 35 U.S.C. 119, filed on Dec. 27, 2023 in the Korean Intellectual Property Office, the entire contents of which are herein incorporated by reference.

### BACKGROUND

### 1. Technical Field

Embodiments of the disclosure relate to a light emitting element, a display device including the same, and a method of fabricating the light emitting element.

### 2. Description of the Related Art

Light emitting elements are widely used as light sources in various electronic devices, including display devices. As an example, the light emitting elements are used as light sources in various electronic devices, including portable electronic devices such as smart phones and smart watches, televisions, as well as virtual reality devices and augmented reality devices.

### SUMMARY

Aspects of the disclosure provide a light emitting element with improved reliability and light emission efficiency, a display device including the same, and a method of fabricating the light emitting element.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, there is provided a light emitting element that may include semiconductor layers including a first semiconductor layer, a light emitting layer, and a second semiconductor layer. The light emitting element may further include a multi-insulating film including a first insulating film, a second insulating film, and a third insulating film sequentially surrounding side surfaces of the semiconductor layers, a low refractive index film surrounding the multi-insulating film and having a thickness greater than a thickness of the multi-insulating film, and a reflective film surrounding the low refractive index film and including metal.

In an embodiment, the first insulating film may include a material having dissociation energy in a range of about 7 eV to about 9 eV.

In an embodiment, the first insulating film may include at least one of ZrO₂, SiO₂, HfO₂, Ta₂O₅, and La₂O₃.

In an embodiment, each of the first insulating film and the third insulating film may include at least one of ZrO₂ and HfO₂, and the second insulating film may include at least one of Al₂O₃ and SiO₂.

In an embodiment, the first insulating film, the second insulating film, and the third insulating film may include M1O₂ type oxide, M2₂O₃ type oxide, and M3O₂ type oxide, respectively, and M1 may be metal material, M2 may be metal material, and M3 may be metal material.

In an embodiment, each of the first insulating film and the third insulating film may include at least one of ZrO₂, SiO₂, HfO₂, GeO₂, TiO₂, and TeO₂, and the second insulating film may include at least one of Al₂O₃, Y₂O₃, La₂O₃, Ce₂O₃, Lu₂O₃, Sc₂O₃, and Yb₂O₃.

In an embodiment, each of the first insulating film, the second insulating film, and the third insulating film may have a thickness in a range of about 0.5 nm to about 5 nm.

In an embodiment, a sum of thicknesses of the first insulating film, the second insulating film, and the third insulating film may be about 10 nm or less.

In an embodiment, the multi-insulating film and the low refractive index film may constitute a multi-composite film between the semiconductor layers and the reflective film, and a thickness of the multi-composite film satisfies a range of Equation 1:

$$\frac{λ}{4 n} \times 0.8 \leq t \leq \frac{λ}{4 n} \times 1.2 \qquad [ Equation 1 ]$$

In Equation 1, t may be the thickness of the multi-composite film, λ may be a light emitting wavelength of the light emitting layer, and n may be a composite refractive index of the multi-composite film.

In an embodiment, the low refractive index film may include SiO₂.

In an embodiment, the reflective film may include at least one of aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), and chromium (Cr).

In an embodiment, the reflective film may have a thickness in a range of about 30 nm to about 200 nm.

In an embodiment, the semiconductor layers may have a width in a range of about 0.5 μm to about 10 μm.

In an embodiment, the light emitting element may further include a protective film surrounding the reflective film.

In an embodiment, the light emitting element may further include a contact electrode disposed on the semiconductor layers, and the multi-insulating film, the low refractive index film, the reflective film, and the protective film may further surround a side surface of the contact electrode.

In an embodiment, the side surfaces of the semiconductor layers may have an inclined surface inclined with respect to a first bottom surface of the semiconductor layers.

According to an aspect of the disclosure, there is provided a display device that may include a first electrode, a second electrode, and a light emitting element electrically connected between the first electrode and the second electrode. The light emitting element may include semiconductor layers including a first semiconductor layer, a light emitting layer, and a second semiconductor layer. The light emitting element may further include a multi-insulating film including a first insulating film, a second insulating film, and a third insulating film sequentially surrounding side surfaces of the semiconductor layers, a low refractive index film surrounding the multi-insulating film and having a thickness greater than a thickness of the multi-insulating film, and a reflective film surrounding the low refractive index film and including metal.

In an embodiment, the light emitting element may further include a protective film surrounding the reflective film.

According to an aspect of the disclosure, there is provided a method of fabricating a light emitting element. The method may include sequentially forming a first semiconductor layer, a light emitting layer, and a second semiconductor layer on a substrate, etching the first semiconductor layer, the light emitting layer, and the second semiconductor layer, sequentially forming a multi-insulating film including a first insulating film, a second insulating film, and a third insulating film, a low refractive index film having a thickness greater than a thickness of the multi-insulating film, and a reflective film including a metal, on the substrate, the first semiconductor layer, the light emitting layer, and the second semiconductor layer, and forming a multi-film surrounding side surfaces of the first semiconductor layer, the light emitting layer, and the second semiconductor layer by etching the multi-insulating film, the low refractive index film and the reflective film.

In an embodiment, the method may further include forming a protective film on the reflective film prior to etching the multi-insulating film, the low refractive index film, and the reflective film, and the multi-film may be formed of at least six films including the multi-insulating film, the low refractive index film, the reflective film, and the protective film.

The light emitting element according to embodiments may include semiconductor layers including a first semiconductor layer, a light emitting layer, and a second semiconductor layer, a multi-insulating film including a first insulating film, a second insulating film, and a third insulating film sequentially surrounding the semiconductor layers, a low refractive index film, and a reflective film. In some embodiments, the light emitting element may further include a protective film surrounding the reflective film. According to the light emitting element and the method of fabricating the same according to some embodiments, light emission efficiency of the light emitting element may be improved in addition to improving reliability of the light emitting element.

The display device according to the embodiments may include the light emitting element. Accordingly, light efficiency of the display device may be improved.

However, effects according to the embodiments of the disclosure are not limited to those mentioned above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view illustrating a light emitting element according to an embodiment;

FIG. 2 is a schematic cross-sectional view illustrating a light emitting element according to an embodiment;

FIG. 3 is a schematic plan view illustrating a light emitting element according to an embodiment;

FIG. 4 is a schematic plan view illustrating a light emitting element according to an embodiment;

FIG. 5 is an enlarged schematic cross-sectional view of area A1 of FIG. 1;

FIG. 6 is a schematic cross-sectional view illustrating a light emitting element according to an embodiment;

FIGS. 7 to 13 are schematic cross-sectional views illustrating a method of fabricating a light emitting element according to an embodiment;

FIG. 14 is a schematic perspective view illustrating a display device according to an embodiment;

FIG. 15 is a schematic perspective view illustrating a display device according to an embodiment;

FIG. 16 is a schematic plan view illustrating a display area according to an embodiment;

FIG. 17 is a schematic cross-section view illustrating a display panel according to an embodiment;

FIG. 18 is a schematic cross-section view illustrating a display panel according to an embodiment;

FIG. 19 is a schematic cross-section view illustrating a display panel according to an embodiment;

FIG. 20 is a schematic cross-section view illustrating a display panel according to an embodiment;

FIG. 21 is a schematic view illustrating a virtual reality device including a display device according to an embodiment;

FIG. 22 is a schematic view illustrating a smart device including a display device according to an embodiment;

FIG. 23 is a schematic view illustrating an instrument board and a center fascia of a vehicle including display devices according to an embodiment; and

FIG. 24 is a schematic view illustrating a transparent display device including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

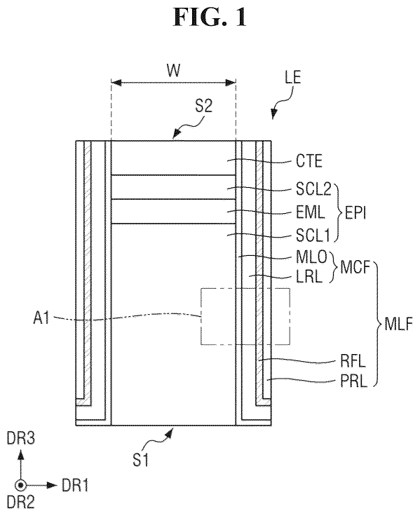

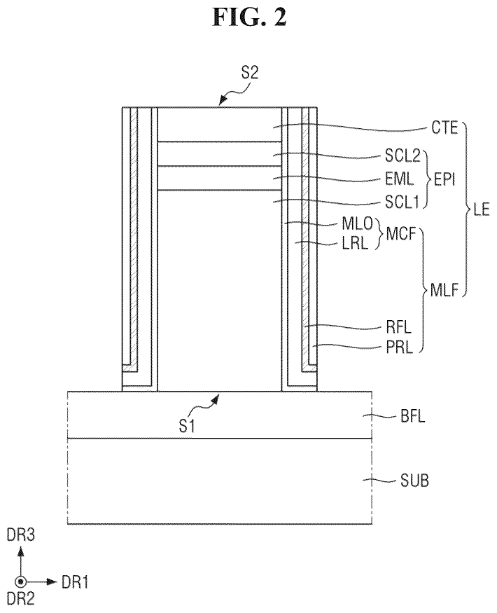

FIG. 1 is a schematic cross-sectional view illustrating a light emitting element LE according to an embodiment. FIG. 2 is a schematic cross-sectional view illustrating a light emitting element LE according to an embodiment. For example, FIG. 1 illustrates only the light emitting element LE, and FIG. 2 illustrates a state in which the light emitting element LE of FIG. 1 is disposed on a substrate SUB.

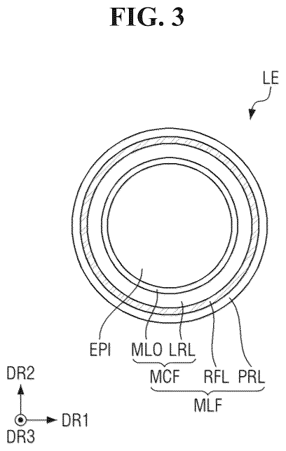

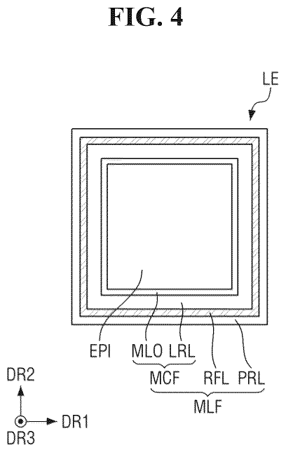

FIG. 3 is a schematic plan view illustrating a light emitting element LE according to an embodiment. FIG. 4 is a schematic plan view illustrating a light emitting element LE according to an embodiment. For example, FIGS. 3 and 4 illustrate different examples with respect to a shape of the light emitting element LE of FIGS. 1 and 2.

Referring to FIGS. 1 to 4, the light emitting element LE may be provided separately from the substrate SUB or may be provided on the substrate SUB. In an embodiment, the light emitting element LE may be formed on a buffer layer BFL on the substrate SUB and separated from the substrate SUB. It is illustrated in FIG. 2 that only one light emitting element LE is disposed on the substrate SUB, but the embodiments are not limited thereto. For example, multiple light emitting elements LE may be disposed on the substrate SUB.

In FIGS. 1 to 4, a first direction DR1, a second direction DR2, and a third direction DR3 that are perpendicular to each other are indicated. As an example, the first direction DR1 and the second direction DR2 may be perpendicular to each other and may define a plane parallel to a first bottom surface S1 of the light emitting element LE or the substrate SUB. The third direction DR3 may be a direction perpendicular to the first direction DR1 and the second direction DR2. As an example, the third direction DR3 may be a direction perpendicular to a main surface of the substrate SUB and may be a height direction or a thickness direction of the substrate SUB or the light emitting element LE. For example, the buffer layer BFL and the light emitting element LE may be sequentially disposed on the substrate SUB along the third direction DR3.

The light emitting element LE may have various forms depending on the embodiments. In an embodiment, the light emitting element LE may include a first bottom surface S1 or a side surface substantially perpendicular to the substrate SUB. As an example, the light emitting element LE may have a substantially rectangular or square shape on the plane defined by the first direction DR1 and the third direction DR3. However, the shape of the light emitting element LE is not limited thereto. As an example, the light emitting element LE may also have a side surface of which at least one portion is inclined in a diagonal direction with respect to the first bottom surface S1 or includes a step-like step.

In an embodiment, the light emitting element LE may have a circular or square shape in plan view as illustrated in FIGS. 3 and 4, but is not limited thereto. As an example, the light emitting element LE may also have a non-quadrangular polygonal shape, an elliptical shape, or other planar shapes.

In an embodiment, the light emitting element LE may be an inorganic light emitting element formed of an inorganic material. For example, the light emitting element LE may be an inorganic light emitting diode formed of nitride-based semiconductor materials (e.g., GaN, AlGaN, GaAlN, InGaN, AlInGaN, AlN, InN, or other nitride-based semiconductor materials), phosphide-based semiconductor materials (e.g., GaP, GaInP, AlGaP, AlInP, AlGaInP, AIP, InP or other phosphide-based semiconductor materials), or other inorganic materials. The light emitting element LE may emit light of a specific color. As an example, the light emitting element LE may emit red light, green light, blue light, or light of another color. The material forming the light emitting element LE or the color of light emitted from the light emitting element LE may vary depending on the embodiments.

In an embodiment, the light emitting element LE may be a micro light emitting diode (LED) having a small size in the micrometer (μm) range. For example, the light emitting element LE may be a micro LED each having a length (e.g., horizontal length or width) in the first direction DR1, a length (e.g., vertical length) in the second direction DR2, and a length (e.g., a thickness or height) in the third direction DR3 of several to hundreds of micrometers. In an embodiment, the length of the light emitting element LE in the first direction DR1, the length thereof in the second direction DR2, and the length thereof in the third direction DR3 may each be about 100 μm or less, but are not limited thereto.

The light emitting element LE may include semiconductor layers EPI and a multi-film MLF surrounding the semiconductor layers EPI. The multi-film MLF may surround side surfaces of the semiconductor layers EPI. In an embodiment, the light emitting element LE may further include a contact electrode CTE disposed on the semiconductor layers EPI. The multi-film MLF may at least partially surround a side surface of the contact electrode CTE, or may not surround the side surface of the contact electrode CTE. As an example, the multi-film MLF may further surround the side surface of the contact electrode CTE along with the side surfaces of the semiconductor layers EPI.

In an embodiment, the light emitting element LE may have a pillar shape, such as a cylinder or a square pillar, and may include a first bottom surface S1 and a second bottom surface S2. In an embodiment, a first semiconductor layer SCL1 of the semiconductor layers EPI may be positioned on the first bottom surface S1, and the contact electrode CTE may be positioned on the second bottom surface S2.

In an embodiment, the light emitting element LE may be disposed so that the first bottom surface S1 faces downward and the second bottom surface S2 faces upward. As an example, the light emitting element LE may be disposed or formed on the substrate SUB so that the first bottom surface S1 thereof faces the substrate SUB. In an embodiment, the light emitting element LE may be separated from the substrate SUB and disposed on a transfer substrate or target substrate, etc., and the arrangement direction of the light emitting element LE may vary depending on the embodiments. As an example, the light emitting element LE may be disposed on the transfer substrate or the object substrate so that the first bottom surface S1 faces upward and the second bottom surface S2 faces downward. In other embodiments, the light emitting element LE may be disposed on the transfer substrate or the target substrate so that the first bottom surface S1 faces downward and the second bottom surface S2 faces upward.

The substrate SUB may be a semiconductor substrate used to fabricate the light emitting element LE. The substrate SUB may be a fabricating substrate or wafer suitable for epitaxial growth. For example, the semiconductor layers EPI of the light emitting element LE may be formed through epitaxial growth on the substrate SUB.

In an embodiment, the substrate SUB may be a substrate including a material such as GaAs, silicon (Si), sapphire, SiC, GaN, or ZnO. As an example, the substrate SUB may be a silicon or sapphire substrate. In case that the epitaxial growth for fabricating the light emitting element LE may be smoothly performed, the type or material of the substrate SUB is not particularly limited. In an embodiment, the substrate SUB may be used as a substrate for epitaxial growth for fabricating the light emitting element LE and finally separated from the light emitting element LE. As an example, after multiple light emitting elements LE are simultaneously formed through epitaxial growth on the substrate SUB, the light emitting elements LE may be separated from the substrate SUB.

The buffer layer BFL may be disposed on the substrate SUB. The buffer layer BFL may be formed to reduce a difference in lattice constant between the semiconductor layers EPI (e.g., the first semiconductor layer SCL1) and the substrate SUB. In an embodiment, the buffer layer BFL may include an undoped semiconductor material. For example, the buffer layer BFL may include an undoped semiconductor layer (e.g., undoped GaN) including a nitride-based semiconductor material, a phosphide-based semiconductor material, or another semiconductor material.

The semiconductor layers EPI may include a first semiconductor layer SCL1, a light emitting layer EML, and a second semiconductor layer SCL2 sequentially disposed in one direction. As an example, the first semiconductor layer SCL1, the light emitting layer EML, and the second semiconductor layer SCL2 may be sequentially disposed or stacked from the first bottom surface S1 to the second bottom surface S2 along the third direction DR3. The semiconductor layers EPI may also be referred to as “semiconductor epitaxial stack” or “epi-layers.”

In an embodiment, the semiconductor layers EPI may be a stacked light emitting structure of micro LEDs with a length or width of approximately several micrometers in the first direction DR1 or the second direction DR2. As an example, the semiconductor layers EPI may have a width W of approximately 0.5 μm to approximately 10 μm in the first direction DR1 or the second direction DR2. However, the size of the semiconductor layers EPI and the light emitting element LE including the same may vary depending on the embodiments.

The first semiconductor layer SCL1 may include a semiconductor material doped with a first conductivity type dopant. For example, the first semiconductor layer SCL1 may include a nitride-based semiconductor material, a phosphide-based semiconductor material, or another semiconductor material, and may be a first conductivity type semiconductor layer that further includes a first conductivity type dopant. In an embodiment, the first semiconductor layer SCL1 may be an n-type semiconductor layer (e.g., n-GaN) doped with an n-type dopant such as Si, Ge, Sn, etc., but is not limited thereto.

The light emitting layer EML may be disposed on the first semiconductor layer SCL1. For example, the light emitting layer EML may be disposed between the first semiconductor layer SCL1 and the second semiconductor layer SCL2. The light emitting layer EML may emit light by recombination of electron-hole pairs generated in response to an electrical signal applied through the first semiconductor layer SCL1 and the second semiconductor layer SCL2.

The light emitting layer EML may include a nitride-based semiconductor material, a phosphide-based semiconductor material, or another semiconductor material, and may have a single or multi-quantum well structure. In an embodiment, the light emitting layer EML may have a multi-quantum well structure including a quantum well layer including InGaN and a barrier layer including GaN, AlGaN, or GaAlN, but is not limited thereto. In an embodiment, in case that the light emitting layer EML includes InGaN, the color of light emitted from the light emitting layer EML may be adjusted or changed by adjusting the content of indium (In).

In an embodiment, the light emitting layer EML may emit light in a visible light wavelength band, for example, light in the wavelength band of approximately 400 nm to approximately 900 nm. For example, the light emitting layer EML may emit blue light with a peak wavelength ranging from approximately 440 nm to approximately 480 nm, green light with a peak wavelength ranging from approximately 510 nm to approximately 550 nm, or red light with a peak wavelength ranging from approximately 610 nm to approximately 650 nm. The light emitting layer EML may emit light in a different color or wavelength band than those mentioned above.

The second semiconductor layer SCL2 may include a semiconductor material doped with a second conductivity type dopant. For example, the second semiconductor layer SCL2 may include a nitride-based semiconductor material, a phosphide-based semiconductor material, or another semiconductor material, and may be a second conductivity type semiconductor layer that further includes a second conductivity type dopant. In an embodiment, the second semiconductor layer SCL2 may be a p-type semiconductor layer (e.g., p-GaN) doped with a p-type dopant such as Mg, Zn, Ca, Se, Ba, etc., but is not limited thereto.

The contact electrode CTE may be disposed on the semiconductor layers EPI. For example, the contact electrode CTE may be disposed on the second semiconductor layer SCL2. The contact electrode CTE may be provided to the light emitting element LE to protect the second semiconductor layer SCL2 and smoothly connect the second semiconductor layer SCL2 to at least one electrode, circuit element, or line.

In an embodiment, the contact electrode CTE may be entirely disposed on the semiconductor layers EPI. For example, the contact electrode CTE may be entirely disposed on the second semiconductor layer SCL2. Accordingly, the contact electrode CTE may appropriately or stably protect the second semiconductor layer SCL2. However, the embodiments are not limited thereto. For example, the contact electrode CTE may be disposed only on a portion of the second semiconductor layer SCL2.

The contact electrode CTE may include metal, metal oxide, or other conductive materials. As an example, the contact electrode CTE may be formed of individually or by mixing a metal such as chromium (Cr), titanium (Ti), aluminum (Al), gold (Au), nickel (Ni), or copper (Cu), oxide or alloy thereof, a transparent conductive material such as indium tin oxide (ITO), indium zinc oxide (IZO), indium tin zinc oxide (ITZO), zinc oxide (ZnO), or indium oxide (In₂O₃). The contact electrode CTE may also be formed of other materials.

The multi-film MLF may wrap or surround the semiconductor layers EPI. For example, the multi-film MLF may wrap or surround side surfaces of the first semiconductor layer SCL1, the light emitting layer EML, and the second semiconductor layer SCL2. In an embodiment in which the light emitting element LE further includes the contact electrode CTE, the multi-film MLF may selectively wrap or surround the contact electrode CTE. For example, the multi-film MLF may partially or entirely surround a side surface of the contact electrode CTE, or may not surround the contact electrode CTE.

The multi-film MLF may expose the first semiconductor layer SCL1 (or another contact electrode provided on the first bottom surface S1 of the light emitting element LE) at the first bottom surface S1 (or the first end including the first bottom surface S1) of the light emitting element LE, and may expose the contact electrode CTE (or the second semiconductor layer SCL2) at the second bottom surface S2 (or the second end including the second bottom surface S2) of the light emitting element LE. For example, the multi-film MLF may not be provided on the first bottom surface S1 (or first end) and the second bottom surface S2 (or second end) of the light emitting element LE. Accordingly, an electrical signal may be applied to the light emitting element LE through the first bottom surface S1 (or first end) and the second bottom surface S2 (or second end) of the light emitting element LE.

The multi-film MLF may be provided on a surface of the light emitting element LE to surround at least the semiconductor layers EPI. The multi-film MLF may protect the semiconductor layers EPI. Accordingly, reliability and electrical stability of the light emitting element LE may be secured. In addition, the multi-film MLF may reflect light generated in the light emitting layer EML and directed to the side surface of the light emitting element LE. Accordingly, a light emission efficiency of the light emitting element LE may be increased.

The multi-film MLF may include a multi-insulating film MLO, a low refractive index film LRL, and a reflective film RFL sequentially surrounding the side surfaces of the semiconductor layers EPI. In an embodiment, the multi-insulating film MLO may be composed of insulating films of three or more films, and the multi-insulating film MLO and the low refractive index film LRL may form a multi-composite film MCF (or composite insulating film) of four or more films. The reflective film RFL may be a single film or a multi-film. In an embodiment, the multi-film MLF may further include a protective film PRL surrounding the reflective film RFL. The protective film PRL may be a single film or a multi-film. The multi-film MFL including the protective film PRL may be composed of films of six or more films sequentially surrounding the side surfaces of the semiconductor layers EPI.

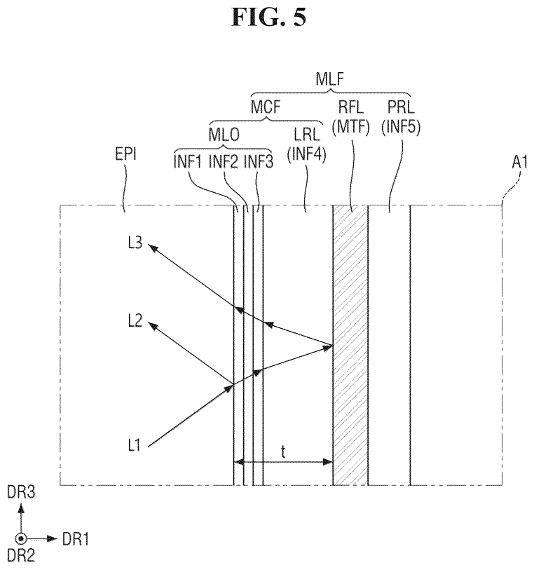

FIG. 5 is an enlarged schematic cross-sectional view of area A1 of FIG. 1. For example, FIG. 5 illustrates details of a multi-film MLF according to an embodiment.

Referring to FIG. 5 in addition to FIGS. 1 to 4, the multi-film MLF may include a multi-composite film MCF and a reflective film RFL. In an embodiment, the multi-film MLF may further include a protective film PRL positioned at the outermost portion.

The multi-composite film MCF may include a multi-insulating film MLO and a low refractive index film LRL. The multi-insulating film MLO and the low refractive index film LRL may sequentially surround the semiconductor layers EPI.

The multi-insulating film MLO may be provided on the surface of the semiconductor layers EPI to secure electrical stability of the light emitting element LE. In addition, the multi-insulating film MLO may block or reduce oxygen from flowing into the semiconductor layers EPI, thereby slowing down a deterioration of the light emitting element LE and increasing the reliability and light emission efficiency of the light emitting element LE. In an embodiment, the multi-insulating film MLO may be made of multiple layers of oxide insulating films including each oxide, and may include oxygen vacancies formed at an interface of the oxide insulating films including different materials. The multi-insulating film MLO may block or reduce oxygen from flowing into the semiconductor layers EPI by capturing oxygen through the oxygen vacancies.

The multi-insulating film MLO may include a first insulating film INF1, a second insulating film INF2, and a third insulating film INF3 sequentially surrounding the side surfaces of the semiconductor layers EPI. In an embodiment, the multi-insulating film MLO may further surround at least a portion of the contact electrode CTE (e.g., a side surface of the contact electrode (CTE)).

The first insulating film INF1 may be directly disposed on the side surfaces of the semiconductor layers EPI to surround the semiconductor layers EPI. In an embodiment, the first insulating film INF1 may include a material having high dissociation energy. As an example, the first insulating film INF1 may include a material having dissociation energy in a range of approximately 7 eV to approximately 9 eV. In an embodiment, the first insulating film INF1 may include an oxide having high dissociation energy, such as zirconium oxide, silicon oxide, hafnium oxide, tantalum oxide, or lanthanum oxide, or other oxides. For example, the first insulating film INF1 may include ZrO₂, SiO₂, HfO₂, Ta₂O₅, or La₂O₃, or other oxides. As the first insulating film INF1 has high dissociation energy, it may be possible to prevent or reduce oxygen dissociation or oxygen diffusion due to the effects of heat energy or electric fields that may occur during the process of fabricating the light emitting element LE or the operation of the light emitting element LE, or oxygen diffusion due to the oxygen dissociation. Accordingly, it may be possible to prevent or reduce oxygen from flowing into the semiconductor layers EPI and stably protect the semiconductor layers EPI.

The second insulating film INF2 may surround the first insulating film INF1. In an embodiment, the second insulating film INF2 may include an oxide different from the oxide included in the first insulating film INF1. In an embodiment, the second insulating film INF2 may include an oxide that may adequately protect the light emitting element LE while generating oxygen vacancies sufficient to improve the deterioration of the light emitting element LE at each interface where it meets the first insulating film INF1 and the third insulating film INF3. In an embodiment, the second insulating film INF2 may include silicon oxide or aluminum oxide. For example, the second insulating film INF2 may include SiO₂ or Al₂O₃. In an embodiment, the second insulating film INF2 includes a material having relatively high dissociation energy (e.g., dissociation energy of approximately 7 eV to approximately 9 eV), and thus may stably protect the semiconductor layers EPI, but the embodiments are not limited thereto.

The third insulating film INF3 may surround the second insulating film INF2. In an embodiment, the third insulating film INF3 may include an oxide different from the oxide included in the second insulating film INF2. In an embodiment, the third insulating film INF3 may include an oxide that may reduce or minimize of defects of the light emitting element LE while generating oxygen vacancies sufficient to improve the deterioration of the light emitting element LE at an interface where it meets the second insulating film INF2. In an embodiment, the third insulating film INF3 includes a material having relatively high dissociation energy (e.g., dissociation energy of approximately 7 eV to approximately 9 eV), and thus may stably protect the semiconductor layers EPI, but the embodiments are not limited thereto. In an embodiment, the third insulating film INF3 may include the same oxide as the oxide included in the first insulating film INF1. For example, the third insulating film INF3 may include zirconium oxide (e.g., ZrO₂), silicon oxide (e.g., SiO₂), hafnium oxide (e.g., HfO₂), tantalum oxide (e.g., Ta₂O₅), and lanthanum oxide (e.g., La₂O₃), or other oxides.

In an embodiment, the multi-insulating film MLO may be made of a combination of materials that may block oxygen from flowing into the semiconductor layers EPI and improve the reliability of the semiconductor layers EPI. For example, the first insulating film INF1 and the third insulating film INF3 may include ZrO₂ or HfO₂, and the second insulating film INF2 may include SiO₂ or Al₂O₃. As an example, the first insulating film INF1, the second insulating film INF2, and the third insulating film INF3 may each include ZrO₂, SiO₂, and ZrO₂, and accordingly, the multi-insulating film MLO may have a triple film structure of ZrO₂/SiO₂/ZrO₂. In other embodiments, the first insulating film INF1, the second insulating film INF2, and the third insulating film INF3 may each include ZrO₂, Al₂O₃, and ZrO₂, and accordingly, the multi-insulating film MLO may have a triple film structure of ZrO₂/Al₂O₃/ZrO₂. In other embodiments, the first insulating film INF1, the second insulating film INF2, and the third insulating film INF3 may each include HfO₂, Al₂O₃, and HfO₂, and accordingly, the multi-insulating film MLO may have a triple film structure of HfO₂/Al₂O₃/HfO₂. The multi-insulating film MLO may have a multi-film structure based on a combination of other materials. As the multi-insulating film MLO appropriately protects the semiconductor layers EPI and blocks or reduces oxygen from flowing into the light emitting layer EML, etc., a quantum efficiency and light emission efficiency of the light emitting element LE may be improved or secured, and deterioration of the light emitting element LE may be suppressed to improve the reliability of the light emitting element LE.

In an embodiment, the first insulating film INF1, the second insulating film INF2, and the third insulating film INF3 may each include M1O₂ type (or MO₂ type) oxide, M2₂O₃ type (or M₂O₃ type) oxide, and M3O₂ (or MO₂ type) oxide. Here, the M or the M1, M2, and M3 are substances that are combined with oxygen (or oxygen ion), and for example, each may be a metal substance (or metal ion). For example, the first insulating film INF1, the second insulating film INF2, and the third insulating film INF3 may each include M1O₂ type (or MO₂ type) metal oxide, M2₂O₃ type (or M₂O₃ type) metal oxide, and M3O₂ (or MO₂ type) metal oxide. At least two of M1, M2, and M3 may be the same material, or M1, M2, and M3 may be different materials. As an example, M1 and M3 may be the same material, and M2 may be a different material from M1 and M3, but the embodiments are not limited thereto.

In an embodiment, the oxide used to form the first insulating film INF1, the second insulating film INF2, and the third insulating film INF3 may be a material selected to reduce or minimize defects of the light emitting element LE while generating oxygen vacancies sufficient to improve the deterioration of the light emitting element LE at interfaces of the insulating films. In an embodiment, each of the first insulating film INF1 and the third insulating film INF3 may include zirconium oxide, silicon oxide, hafnium oxide, germanium oxide, titanium oxide, or tellurium oxide. For example, each of the first insulating film INF1 and the third insulating film INF3 may include ZrO₂, SiO₂, HfO₂, GeO₂, TiO₂, or TeO₂. The first insulating film INF1 and the third insulating film INF3 may include the same oxide or different oxides.

In an embodiment, the second insulating film INF2 may include aluminum oxide, yttrium oxide, lanthanum oxide, cerium oxide, lutetium oxide, scandium oxide, or ytterbium oxide. For example, the second insulating film INF2 may include Al₂O₃, Y₂O₃, La₂O₃, Ce₂O₃, Lu₂O₃, Sc₂O₃, or Yb₂O₃.

In an embodiment, the first insulating film INF1, the second insulating film INF2, and the third insulating film INF3 may each include ZrO₂, Al₂O₃, and ZrO₂, and accordingly, the multi-insulating film MLO may have a triple film structure of ZrO₂/Al₂O₃/ZrO₂. At interfaces where the second insulating film INF2 is in contact with the first insulating film INF1 and the third insulating film INF3, oxygen vacancies may be formed due to an interface reaction. As an example, at the interfaces, Al₂O₃ of the second insulating film INF2 may react with ZrO₂ of the first insulating film INF1 and ZrO₂ of the third insulating film INF3, thereby forming oxygen vacancies. For example, at the interfaces where the second insulating film INF2 is in contact with the first insulating film INF1 and the third insulating film INF3, Al₂O₃ of the second insulating film INF2 reacts with 2ZrO₂ (ZrO₂ of the first insulating film INF1 and ZrO₂ of the third insulating film INF3) of the first and third insulating films INF1 and INF3, so that zirconium (Zr) may be placed in place of aluminum (Al), and oxygen (O) may be substituted for each other. At interfaces where the second insulating film INF2 are in contact with the first and third insulating films INF1 and INF3, since the ratio of oxygen (O) ions in the first and third insulating films INF1 and INF3 and oxygen (O) ions in the second insulating film INF2 is 4:3, three oxygen ions enter three of the four oxygen sites, and one oxygen site is left empty, which may cause an oxygen vacancy. The oxygen vacancies formed by the interface reaction are defects fixed to adjacent atoms and may not move even while the light emitting element LE is operating. The oxygen vacancies formed at the interfaces of the first insulating film INF1, the second insulating film INF2, and the third insulating film INF3 may function as capture sites that capture oxygen flowing into the light emitting element LE, thereby suppressing oxygen from being diffused into the semiconductor layers EPI. Accordingly, deterioration of the light emitting element LE may be reduced or minimized, and reliability of the light emitting element LE may be increased.

The first insulating film INF1, the second insulating film INF2, and the third insulating film INF3 may be formed as thin films with a limited thickness enough to reduce or minimize the impact on the semiconductor layers EPI. In an embodiment, the oxide used to form the first insulating film INF1, the second insulating film INF2, and the third insulating film INF3 may be formed with a limited thickness to reduce or minimize defects of the light emitting element LE while smoothly inducing the interface reaction that generates oxygen vacancies sufficient to improve the deterioration of the light emitting element LE at interfaces of the insulating films. For example, the thickness of each of the first insulating film INF1, the second insulating film INF2, and the third insulating film INF3 may be in a range of approximately 0.5 nm to approximately 5 nm. In addition, a sum of the thicknesses of the first insulating film INF1, the second insulating film INF2, and the third insulating film INF3, for example, a thickness of the multi-insulating film MLO, may be approximately 10 nm or less. In an embodiment, the thickness of each of the first insulating film INF1, the second insulating film INF2, and the third insulating film INF3 may be limited to a narrower range of approximately 0.5 nm to approximately 3 nm, thereby minimizing the impact on the light emitting layer EML.

In an embodiment, the second insulating film INF2 may be formed to have a thickness of approximately 2 nm or less (e.g., a thickness in a range of approximately 1 nm to approximately 2 nm) to smoothly induce the interface reaction. The first insulating film INF1 may be formed to have a greater thickness than the second insulating film INF2 to prevent defects from occurring in areas too close to the semiconductor layers EPI (e.g., to secure a certain distance or more between the interface of the first insulating film INF1 and the second insulating film INF2 and the semiconductor layers EPI), and may be formed to have a limited thickness to reduce or minimize the impact on the semiconductor layers EPI. As an example, the first insulating film INF1 may be formed to have a thickness of approximately 3 nm or less (e.g., a thickness in a range of approximately 2 nm to approximately 3 nm). The third insulating film INF3 may be formed to have a thickness greater than or equal to the thickness of the second insulating film INF2 so that the interface reaction may occur relatively uniformly at the interface between the first insulating film INF1 and the second insulating film INF2 and the interface between the second insulating film INF2 and the third insulating film INF3 (e.g., the interface reaction is not concentrated at the interface between the first insulating film INF1 and the second insulating film INF2). As an example, the third insulating film INF3 may be formed to have a thickness of approximately 2 nm or approximately 3 nm or less (e.g., a thickness in a range of approximately 1 nm to approximately 3 nm). Accordingly, the reliability of the light emitting element LE may be increased by reducing or minimizing defects of the light emitting element LE and improving the deterioration of the light emitting element LE.

The low refractive index film LRL may surround the multi-insulating film MLO. For example, the low refractive index film LRL may surround the third insulating film INF3. The low refractive index film LRL may surround the side surfaces of the semiconductor layers EPI and/or the contact electrode CTE with the multi-insulating film MLO between the low refractive index film LRL and the semiconductor layers EPI and/or the contact electrode CTE.

The low refractive index film LRL may include a low refractive index material (e.g., SiO₂) so that at least some of light transmitted through the multi-insulating film MLO may transmit through the low refractive index film LRL and reach the reflective film RFL. As an example, the low refractive index film LRL may be made of a fourth insulating film INF4 including SiO₂, or may be made of a multi-film including the fourth insulating film INF4.

In an embodiment, the low refractive index film LRL may have a greater thickness than the multi-insulating film MLO. For example, the low refractive index film LRL may have a thickness greater than the sum of the thicknesses of the first insulating film INF1, the second insulating film INF2, and the third insulating film INF3.

In an embodiment, the low refractive index layer (LRL) may be formed to have an appropriate thickness to increase or maximize a reflectance of light generated from the light emitting element LE and reflected from the multi-film MLF. For example, a multi-composite film MCF including the multi-insulating film MLO and the low refractive index film LRL may be interposed between the semiconductor layers EPI and the reflective film RFL to form a composite refractive film, and may have a thickness that causes a resonance phenomenon with respect to a light emitting wavelength of the light emitting element LE. For example, in case that a light emitting wavelength of the light emitting layer EML (or light emitting element LE) (e.g., a peak wavelength of light generated in the light emitting layer EML) is λ, and a composite refractive index of the multi-composite film MCF is n, the multi-composite film MCF may have a thickness of λ/(4n).

In an embodiment, the multi-composite film MCF may have a thickness in a predetermined or selected range (e.g., a range of ±20%) centered on the thickness of λ/(4n). For example, the thickness of the multi-composite film MCF corresponding to a sum of the thickness of the multi-insulating film MLO and the thickness of the low refractive index film LRL (e.g., a sum of the thicknesses of the first insulating film INF1, the second insulating film INF2, the third insulating film INF3, and the fourth insulating film INF4) may be included in or satisfy a range of Equation 1 below.

$$\frac{λ}{4 n} \times 0.8 \leq t \leq \frac{λ}{4 n} \times 1.2 \qquad [ Equation 1 ]$$

In Equation 1, t may be the thickness of the multi-composite film MCF, λ may be the light emitting wavelength of the light emitting layer EML (or light emitting element LE) (e.g., the peak wavelength of light generated in the light emitting layer EML), and n may be the composite refractive index of the multi-composite film MCF.

As an example, in case that the light emitting wavelength 2 of the light emitting layer EML is approximately 460 nm, the thickness of the multi-insulating film MLO is limited to approximately 10 nm or less, and the low refractive index film LRL is made of SiO₂, the multi-composite film MCF may be formed to have the thickness t of approximately 80 nm. However, this may vary depending on a complex refractive index depending on the material and thickness of the multi-insulating film MLO and low refractive index film LRL.

In other embodiments, in case that a resonance effect caused by the multi-composite film MCF is actually caused by the resonance phenomenon caused by the low refractive index film LRL, t is a total thickness of the multi-composite film MCF, A is a light emitting wavelength of the light emitting layer EML, and n may be a refractive index of the low refractive index film LRL.

In embodiments, a central value (or reference value) of the thickness t of the multi-composite film MCF is not limited to only the λ/(4n) value, and the thickness t of the multi-composite film MCF may be changed to different values in a range where reflected light may be enhanced or optimized. For example, the central value of the thickness t of the multi-composite film MCF may be a value corresponding to a multiple (e.g., an integer multiple) of λ/(4n).

In an embodiment, the thickness t of the multi-composite film MCF may be a value in a range including multiples of λ/(4n) and adding a predetermined or selected margin value. For example, the thickness t of the multi-composite film MCF may be a value in a specific range based on a multiple of λ/(4n). As an example, the thickness t of the multi-composite film MCF may be a value in a range of a lower limit value minus a margin value of approximately 15% and an upper limit value plus a margin value of approximately 15%, with a multiple of λ/(4n) as the central value. In other embodiments, the thickness t of the multi-composite film MCF may be a value in a range of a lower limit value minus a margin value of approximately 20% and an upper limit value plus a margin value of approximately 20%, with a multiple of λ/(4n) as the central value. As an example, the thickness of the multi-composite film MCF may be included in a range of Equation 2 below.

$$\frac{λ}{4 n} \times k \times 0.8 \leq t \leq \frac{λ}{4 n} \times k \times 1.2 \qquad [ Equation 2 ]$$

In Equation 2, t may be the thickness of the multi-composite film MCF, λ may be the light emitting wavelength of the light emitting layer EML (or light emitting element LE), n may be the composite refractive index of the multi-composite film MCF, and k may be an integer (or natural number).

As such, in the embodiments, the thickness of the multi-composite film MCF may be appropriately adjusted or set in a range where reflected light by the multi-film MLF may be enhanced.

The reflective film RFL may surround the low refractive index film LRL. The reflective film RFL may surround the side surfaces of the semiconductor layers EPI and/or the contact electrode CTE with the multi-composite film MCF between the reflective film RFL and the semiconductor layers EPI and/or the contact electrode CTE.

In an embodiment, the reflective film RFL may include a metal having high light reflectivity. For example, the reflective film RFL may include at least one metal with high reflectivity, such as aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr), or at least one metal film MTF including other reflective materials. The reflective film RFL may reflect light that transmits through the low refractive index film LRL and reaches the reflective film RFL.

In an embodiment, the reflective film RFL may be formed to a thickness that may be readily formed during the fabricating process while appropriately securing light reflectivity. As an example, the reflective film RFL may have a thickness in a range of approximately 30 nm to approximately 200 nm.

According to embodiments, at least a portion of light L1 traveling from the semiconductor layers EPI toward the multi-film MLF may be reflected at the interface between the semiconductor layers EPI and the multi-composite film MCF, and at least a portion of light transmitted through the multi-film MLF may be reflected at the interface between the multi-composite film MCF and the reflective film RFL. In embodiments, as the multi-composite film MCF is formed to have the thickness t that may obtain the resonance effect, the reflected light by the multi-film MLF may be enhanced and the reflectivity of the light emitting element LE may be increased or maximized due to constructive interference between reflected light L2 reflected at the interface of the semiconductor layers EPI and the multi-composite film MCF and reflected light L3 reflected at the interface of the multi-composite film MCF and the reflective film RFL. Accordingly, loss of light generated from the light emitting element LE may be prevented or reduced, and light emission efficiency of the light emitting element LE may be improved.

The protective film PRL may surround the reflective film RFL. For example, the protective film PRL may wrap or surround at least the side surfaces of the semiconductor layers EPI and may be disposed on the outermost portion of the light emitting element LE. In an embodiment, the protective film PRL may at least partially wrap or surround the side surface of the contact electrode CTE.

The protective film PRL may be an insulating film of a single film or a multi-film. For example, the protective film PRL may be made of a single film or a multi-film including at least a fifth insulating film INF5. The protective film PRL may include at least one insulating material of silicon oxide (e.g., SiO₂), silicon nitride (e.g., Si₃N₄), aluminum oxide (e.g., Al₂O₃), titanium oxide (e.g., TiO₂), and hafnium oxide (e.g., HfO₂), or other insulating materials. The protective film PRL may secure or improve electrical stability of the light emitting element LE by protecting the reflective film RFL, etc., and preventing short circuit defects in the light emitting element LE. In addition, as the protective film PRL appropriately or stably protects the light emitting element LE, the reliability of the light emitting element LE may be further improved. The protective film PRL may be formed to have a thickness that may be readily formed during the fabricating process while stably protecting the light emitting element LE. As an example, the protective film PRL may have a thickness in a range of approximately 10 nm to approximately 200 nm, but is not limited thereto.

As described above, the light emitting element LE according to the embodiments may include the multi-insulating film MLO, the low refractive index film LRL, and the reflective film RFL sequentially surrounding the semiconductor layers EPI. In some embodiments, the light emitting element LE may further include a protective film PRL surrounding the reflective film RFL. According to the embodiments, the protective film PRL may reduce or block oxygen from flowing into the semiconductor layers EPI and prevent short circuit defects in the light emitting element LE. Accordingly, the reliability and lifespan of the light emitting element LE may be improved, and the electrical stability of the light emitting element LE may be secured. In addition, the light traveling to the multi-film MLF may be appropriately or effectively reflected by the multi-composite film MCF including the multi-insulating film MLO and the low refractive index film LRL and the reflective film RFL. Accordingly, a light emission efficiency of the light emitting element LE may be improved.

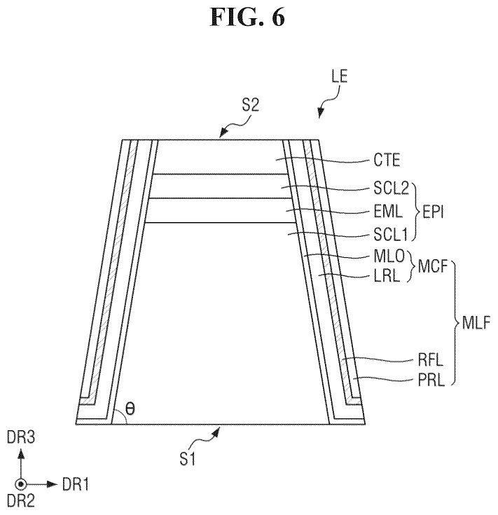

FIG. 6 is a schematic cross-sectional view illustrating a light emitting element LE according to an embodiment. For example, FIG. 6 illustrates an embodiment that is different from FIG. 1 with respect to the shape of the light emitting element LE.

Referring to FIG. 6 in addition to FIGS. 1 to 5, the light emitting element LE may include a side surface (e.g., an inclined side wall) that is inclined with respect to the first bottom surface S1 and/or the second bottom surface S2. For example, the side surfaces of the semiconductor layers EPI may have an inclined surface inclined at an angle θ of approximately 60 to 90 degrees with respect to the first bottom surface S1 or the cross section of the semiconductor layers EPI. The multi-film MLF surrounding the semiconductor layers EPI may be formed in the form of an inclined surface inclined at an angle θ corresponding to the side surfaces of the semiconductor layers EPI with respect to the first bottom surface S1 or the cross section of the light emitting element LE. As an example, the side surfaces of the semiconductor layers EPI and the multi-film MLF may be formed as an inclined surface having an angle θ of 90 degrees or less with respect to the first bottom surface S1 or the cross section of the light emitting element LE. Accordingly, an efficiency of light emitted from the first bottom surface S1 of the light emitting element LE may be increased.

In an embodiment, the light emitting element LE may be disposed on a display panel, etc., with the first bottom surface S1 facing upward, and the display panel may be a front-emitting display panel that emits light in an upward direction. By increasing the efficiency of light emitted from the light emitting element LE through the first bottom surface S1, a light emission efficiency of the display panel may be increased.

The arrangement direction or the shape of the side (e.g., inclined surface) of the light emitting element LE may vary depending on the embodiments. For example, considering the light emission efficiency of the light emitting element LE and the electronic device (e.g., display panel) including the same, the arrangement direction or shape (e.g., the shape of the side surface) of the light emitting element LE may be variously adjusted or changed.

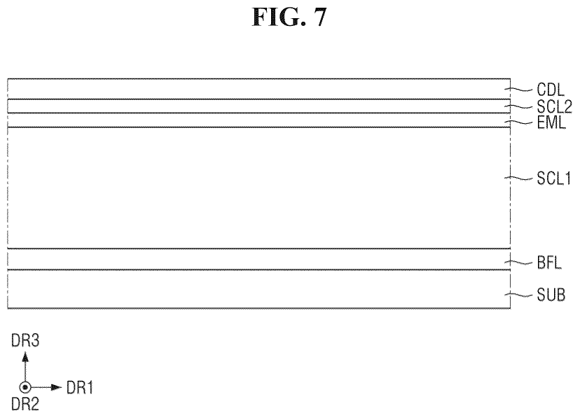

FIGS. 7 to 13 are schematic cross-sectional views illustrating a method of fabricating a light emitting element LE according to an embodiment. For example, FIGS. 7 to 13 sequentially illustrate fabricating steps for fabricating the light emitting element LE according to the embodiments of FIGS. 1 to 5. The light emitting element LE according to the embodiment of FIG. 6 may be fabricated in a substantially similar manner to the light emitting element LE according to the embodiments of FIGS. 1 to 5. For example, the light emitting element LE according to the embodiment of FIG. 6 may be fabricated in a substantially similar or identical manner to the light emitting element LE according to the embodiments of FIGS. 1 to 5, except that the semiconductor layers EPI and contact electrode CTE may be etched to have side surfaces in the form of an inclined surface, and thus the multi-film MLF may also be formed in the form of an inclined surface.

Referring to FIG. 7, a substrate SUB for fabricating a light emitting element LE may be prepared, and a first semiconductor layer SCL1, a light emitting layer EML, and a second semiconductor layer SCL2 may be sequentially formed on the substrate SUB. In case fabricating a light emitting element LE including a contact electrode CTE, a conductive layer CDL for forming the contact electrode CTE may be further formed on the second semiconductor layer SCL2. In an embodiment, a buffer layer BFL may be first formed on the substrate SUB, and a first semiconductor layer SCL1, a light emitting layer EML, a second semiconductor layer SCL2, and a conductive layer CDL may be sequentially formed on the buffer layer BFL.

The substrate SUB may be a semiconductor substrate suitable for epitaxial growth. The substrate SUB may be a semiconductor substrate including the materials mentioned above.

The buffer layer BFL may be formed of the semiconductor material mentioned above, and may be entirely formed on the substrate SUB through epitaxial growth. As an example, the buffer layer BFL may be formed on the substrate SUB by epitaxial growth using process technology such as metal-organic chemical vapor deposition (MOCVD), metal-organic vapor phase epitaxy (MOVPE), molecular beam epitaxy (MBE), liquid phase epitaxy (LPE), or vapor phase epitaxy (VPE).

The semiconductor layers EPI may be formed of the semiconductor materials mentioned above, and may be sequentially formed on the buffer layer BFL (or substrate SUB) by epitaxial growth. The semiconductor layers EPI may first be entirely formed on the buffer layer BFL.

For example, the first semiconductor layer SCL1 may be formed on the buffer layer BFL by epitaxial growth using the nitride-based or phosphide-based semiconductor material mentioned above, or other semiconductor materials. The first semiconductor layer SCL1 may be doped to include a first conductivity type dopant (e.g., n-type dopant).

The light emitting layer EML may be formed on the first semiconductor layer SCL1 by epitaxial growth using the nitride-based or phosphide-based semiconductor material mentioned above, or other semiconductor materials. In an embodiment, the light emitting layer EML having a multi-quantum well structure may be formed by alternately and/or repeatedly forming a barrier layer and a quantum well layer on the first semiconductor layer SCL1.

The second semiconductor layer SCL2 may be formed on the light emitting layer EML by epitaxial growth using the nitride-based or phosphide-based semiconductor material mentioned above, or other semiconductor materials. The second semiconductor layer SCL2 may be doped to include a second conductivity type dopant (e.g., p-type dopant).

The conductive layer CDL may be formed on the semiconductor layers EPI using the conductive materials previously mentioned as the materials of the contact electrode CTE or other conductive materials. In an embodiment, the conductive layer CDL may be entirely formed on the second semiconductor layer SCL2. As an example, the conductive layer CDL may be formed by entirely depositing a conductive material on the substrate SUB on which the semiconductor layers EPI are formed.

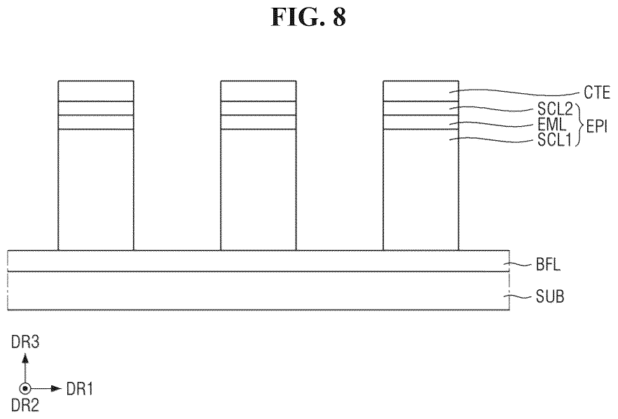

Referring to FIG. 8, the first semiconductor layer SCL1, the light emitting layer EML, the second semiconductor layer SCL2, and the conductive layer CDL may be etched to a size and/or shape corresponding to each light emitting element LE to be manufactured. As a result, the semiconductor layers EPI and contact electrode CTE of the light emitting element LE may be formed. In an embodiment, the first semiconductor layer SCL1, the light emitting layer EML, the second semiconductor layer SCL2, and the conductive layer CDL may be etched by a single mask process, and accordingly, the contact electrode CTE may be formed in a size and shape corresponding to the size and shape of the semiconductor layers. However, the embodiments are not limited thereto. For example, the contact electrode CTE may be formed in a different size and/or shape than the semiconductor layers EPI.

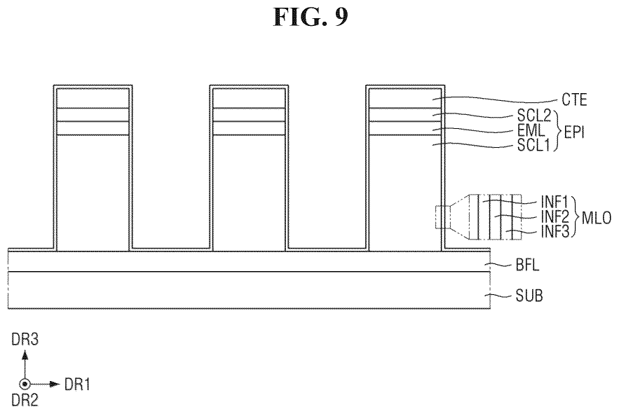

Referring to FIGS. 9 to 12, films for forming the multi-film MLF disclosed in FIG. 1 and the like may be sequentially formed on the substrate SUB on which the semiconductor layers EPI and the contact electrode CTE are formed. In an embodiment, the films for forming the multi-film MLF may first be entirely formed on the substrate SUB.

For example, first, as illustrated in FIG. 9, a multi-insulating film MLO may be entirely formed on the substrate SUB, the buffer layer BFL, the first semiconductor layer SCL1, the light emitting layer EML, the second semiconductor layer SCL2, and the contact electrode CTE. In an embodiment, by sequentially forming a first insulating film INF1, a second insulating film INF2, and a third insulating film INF3 on the substrate SUB on which the semiconductor layers EPI and the contact electrode CTE are formed, a multi-insulating film MLO including the first insulating film INF1, the second insulating film INF2, and the third insulating film INF3 may be formed. As an example, after the first insulating film INF1 is entirely formed (e.g., deposited) on the substrate SUB on which the semiconductor layers EPI and the contact electrode CTE are formed, the second insulating film INF2 may be entirely formed on the first insulating film INF1, and the third insulating film INF3 may be entirely formed on the second insulating film INF2. The first insulating film INF1, the second insulating film INF2, and the third insulating film INF3 may be formed of each of the insulating materials mentioned above (e.g., each of the oxides mentioned above). In addition, the first insulating film INF1, the second insulating film INF2, and the third insulating film INF3 may be formed to have the thickness mentioned above. As an example, the first insulating film INF1, the second insulating film INF2, and the third insulating film INF3 may each be formed to have a thickness in a range of approximately 0.5 nm to approximately 5 nm or approximately 0.5 nm to approximately 3 nm, and the multi-insulating film MLO including the first insulating film INF1, the second insulating film INF2, and the third insulating film INF3 may be formed to have a thickness of approximately 10 nm or less.

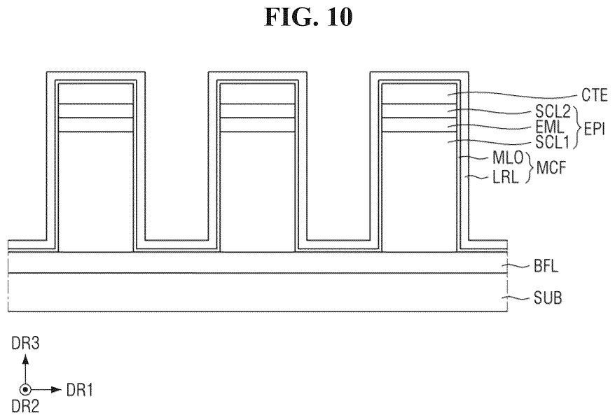

Thereafter, as illustrated in FIG. 10, a low refractive index film LRL may be entirely formed on the multi-insulating film MLO. The low refractive index film LRL may form the multi-composite film MCF together with the multi-insulating film MLO. In an embodiment, the low refractive index film LRL may be formed to have a thickness in which a total thickness t of the multi-insulating film MLO and the low refractive index film LRL satisfies a thickness that may obtain a resonance effect for the light emitting wavelength 2 of the light emitting layer (EML). For example, the low refractive index film LRL may be formed of the materials (e.g., SiO₂ or other low refractive materials) and thicknesses (e.g., thickness of a value obtained by subtracting the thickness of the multi-insulating film MLO from the thickness t of the multi-composite film MCF that may obtain the resonance effect) described above.

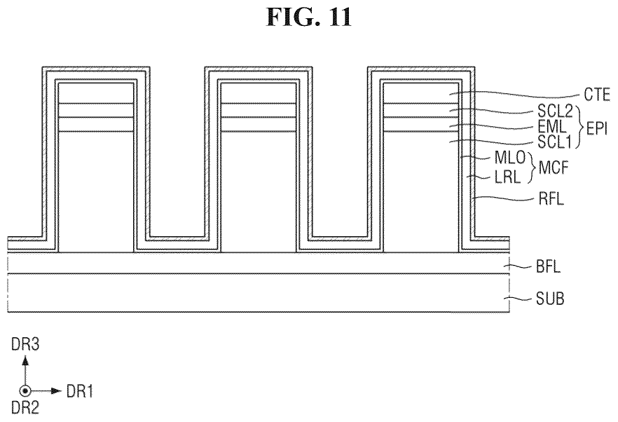

Thereafter, as illustrated in FIG. 11, a reflective film RFL may be entirely formed on the low refractive index film LRL. In an embodiment, the reflective film RFL may be formed of the material (e.g., a metal with high reflectivity such as aluminum (Al)) and thickness (e.g., a thickness in a range of approximately 30 nm to approximately 200 nm) mentioned above.

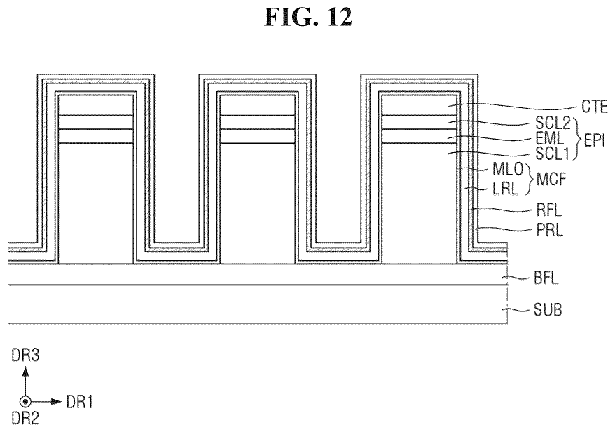

Thereafter, as illustrated in FIG. 12, a protective film PRL may be entirely formed on the reflective film RFL. In an embodiment, the protective film PRL may be formed of the material (e.g., an insulating material including SiO₂) and thickness (e.g., a thickness in a range of approximately 10 nm to approximately 200 nm) mentioned above. The protective film PRL may be an element disposed on the outermost portion of the light emitting element LE, and the material and thickness of the protective film PRL are not particularly limited as long as the light emitting element LE may be properly protected and the electrical stability of the light emitting element LE may be secured.

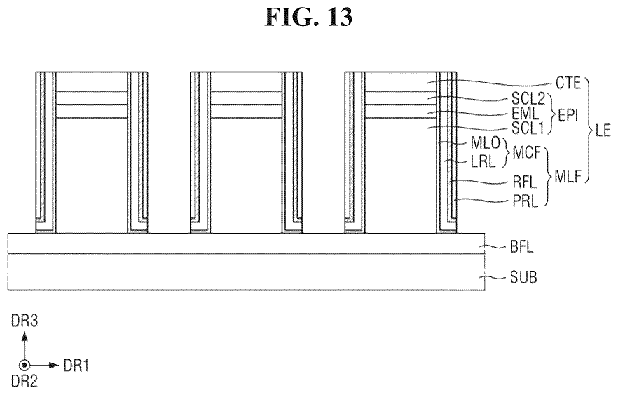

Referring to FIG. 13, by etching the multi-insulating film MLO, the low refractive index film LRL, the reflective film RFL, and the protective film PRL, a multi-film MLF may be formed on the side surfaces of the semiconductor layers EPI, and at least a portion of the contact electrode CTE may be exposed. For example, by entirely etching the multi-insulating film MLO, the low refractive index film LRL, the reflective film RFL, and the protective film PRL, the multi-film MLF surrounding the side surfaces of the semiconductor layers EPI and the contact electrode CTE may be formed, and an upper surface of the contact electrode CTE may be exposed.

In an embodiment, the multi-film MLF may be formed of five films or more. As an example, the multi-film MLF may be formed of at least five films including the multi-insulating film MLO, the low refractive index film LRL, and the reflective film RFL of a triple film. In an embodiment, the multi-film MLF may further include a protective film PRL, and thus may be formed of at least six films.

In an embodiment, in case fabricating a light emitting element LE (or light emitting elements LE) separated from the substrate SUB or transferring the light emitting element LE to a transfer substrate or target substrate (e.g., a backplane substrate of a display panel), a process of separating the light emitting element LE from the substrate SUB and the buffer layer BFL may be additionally performed. In an embodiment, the substrate SUB and the buffer layer BFL may be separated from the light emitting element LE by electrical and/or chemical etching, laser lift-off, or other methods.

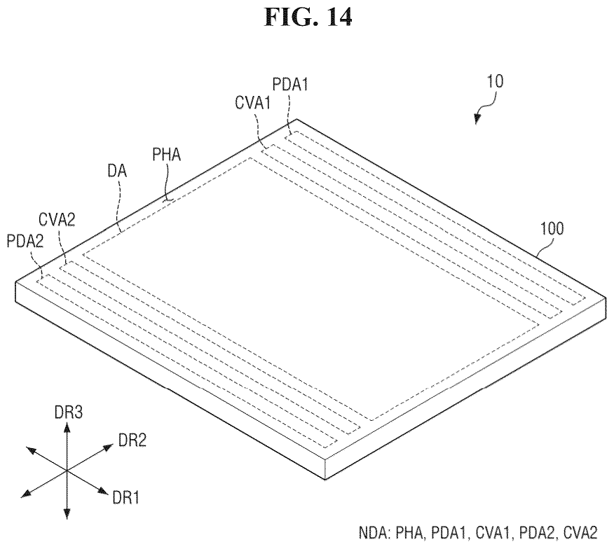

FIG. 14 is a schematic perspective view illustrating a display device 10 according to an embodiment.

Referring to FIG. 14, a display device 10 according to an embodiment may include a display panel 100 including a display area DA and a non-display area NDA. In an embodiment, the display device 10 may be an ultra-small display device applied to a virtual reality device or an augmented reality device, but is not limited thereto.

In an embodiment, the display panel 100 may have a quadrangular planar shape having long sides in the first direction DR1 and short sides in the second direction DR2. In FIG. 14, the first direction DR1 may indicate a horizontal direction of the display panel 100, and the second direction DR2 may indicate a vertical direction of the display panel 100. The third direction DR3 may indicate a thickness direction or height direction of the display panel 100. However, the planar shape of the display panel 100 is not limited thereto, and the display panel 100 may also have a different shape. For example, the display panel 100 may have a polygonal shape other than a square shape, a circular shape, an elliptical shape, or an irregular planar shape.

The display area DA may be an area where an image is displayed and may include pixels (or light emitting elements LE). In an embodiment, a planar shape of the display area DA may follow the planar shape of the display panel 100. It is illustrated in FIG. 1 that the display area DA has a quadrangular planar shape. The display area DA may be disposed in a central area of the display panel 100.

The non-display area NDA may be an area where an image is not displayed and may be positioned adjacent to the display area DA. As an example, the non-display area NDA may surround the display area DA.

The non-display area NDA may include a first common voltage supply area CVA1, a second common voltage supply area CVA2, a first pad area PDA1, a second pad area PDA2, and a peripheral area PHA.

The first common voltage supply area CVA1 may be disposed between the first pad area PDA1 and the display area DA. The second common voltage supply area CVA2 may be disposed between the second pad area PDA2 and the display area DA. In an embodiment, the display panel 100 may include only one of the first common voltage supply area CVA1 and the second common voltage supply area CVA2.

Each of the first common voltage supply area CVA1 and the second common voltage supply area CVA2 may include common electrode connection portions electrically connected to a common electrode positioned in the display area DA. The common electrode connection portions may be further connected to common voltage pads positioned in the first pad area PDA1 and/or the second pad area PDA2. The common electrode connection portions may include a conductive material (e.g., a metal material such as aluminum (Al), etc.), and may electrically connect the common electrode of the display area DA and the common voltage pads of the first pad area PDA1 and/or the second pad area PDA2. A common voltage (or low-potential pixel voltage) applied to the first pad area PDA1 and/or the second pad area PDA2 through the common electrode connection portions may be supplied to the light emitting elements LE of the display area DA. FIG. 14 illustrates a display device 10 in which the first common voltage supply area CVA1 and the second common voltage supply area CVA2 are positioned in the non-display area NDA, but embodiments are not limited thereto. For example, at least one of the first common voltage supply area CVA1 and the second common voltage supply area CVA2 may also be positioned in the display area DA.

The first pad area PDA1 may be disposed on one side (e.g., an upper side) of the display panel 100. The first pad area PDA1 may include common voltage pads connected to an external circuit board.

The second pad area PDA2 may be disposed on another side (e.g., a lower side) of the display panel 100. The second pad area PDA2 may include common voltage pads connected to an external circuit board. In an embodiment, the display panel 100 may also include only one of the first pad area PDA1 and the second pad area PDA2.

The peripheral area PHA may be a remaining area excluding the first common voltage supply area CVA1, the second common voltage supply area CVA2, the first pad area PDA1, and the second pad area PDA2 from the non-display area NDA. The peripheral area PHA may surround not only the display area DA, but also the first common voltage supply area CVA1, the second common voltage supply area CVA2, the first pad area PDA1, and the second pad area PDA2.

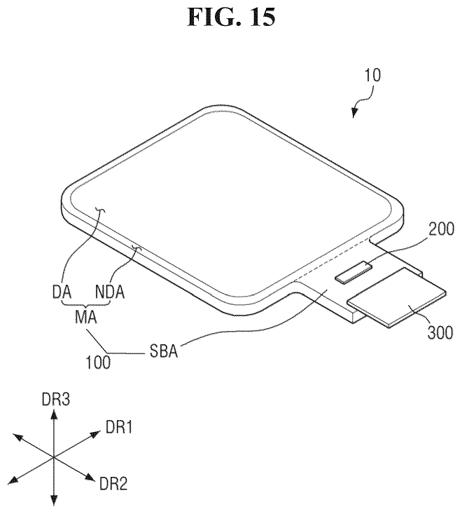

FIG. 15 is a schematic perspective view illustrating a display device 10 according to an embodiment.

Referring to FIG. 15, a display device 10 may include a display panel 100, a display driving circuit 200, and a circuit board 300. In an embodiment, the display device 10 may be a display device applied to a watch, etc., but is not limited thereto.

In an embodiment, the display panel 100 may have a quadrangular planar shape on a plane defined by the first direction DR1 and the second direction DR2. As an example, the display panel 100 may have a substantially rectangular or square planar shape. A corner where the sides of the display panel 100 extending in the first direction DR1 and the sides thereof extending in the second direction DR2 meet may be rounded or may be formed at a right angle. The shape of the display panel 100 may be variously changed depending on the embodiments. For example, the display panel 100 may also have a non-quadrangular polygonal shape, a circular shape, an elliptical shape, or other planar shapes.

The display panel 100 may include a main area MA including a display area DA and a non-display area NDA. The display area DA may be an area where an image is displayed and may include pixels. The non-display area NDA may be disposed around the display area DA and may surround the display area DA.

In an embodiment, the display panel 100 may further include a sub-area SBA extending from the main area MA. In an embodiment, the sub-area SBA may extend from an end of the main area MA in the second direction DR2, and may have a width or length smaller than that of the main area MA in at least one of the first direction DR1 and the second direction DR2. It is illustrated in FIG. 15 that the sub-area SBA is unfolded to be parallel to the main area MA, but the sub-area SBA may be folded or bent. For example, the sub-area SBA may be folded at a portion adjacent to the main area MA, and thus a portion of the sub-area SBA may overlap the main area MA. As an example, a portion of the sub-area SBA in which the display driving circuit 200, etc. is mounted, may be positioned on a rear surface of the main area MA.

The display driving circuit 200 may be disposed in the sub-area SBA, but is not limited thereto. For example, the display driving circuit 200 may be mounted on another circuit board electrically connected to the display panel 100.

The display driving circuit 200 may generate driving signals for driving the display panel 100. In an embodiment, the display driving circuit 200 may be formed as an integrated circuit (IC) and may be attached onto the display panel 100 in a chip on glass (COG) manner, a chip on plastic (COP) manner, an ultrasonic bonding manner, or another manner.

The circuit board 300 may be attached onto an end of the display panel 100. As an example, the circuit board 300 may be attached onto a pad portion of the display panel 100 positioned at an end of the sub-area SBA and electrically connected to the display panel 100 and the display driving circuit 200.

Signals and power voltages for driving the display panel 100 may be supplied to the display panel 100 and the display driving circuit 200 through the circuit board 300. The circuit board 300 may be a flexible film such as a flexible printed circuit board, a printed circuit board, or a chip on film, but is not limited thereto.

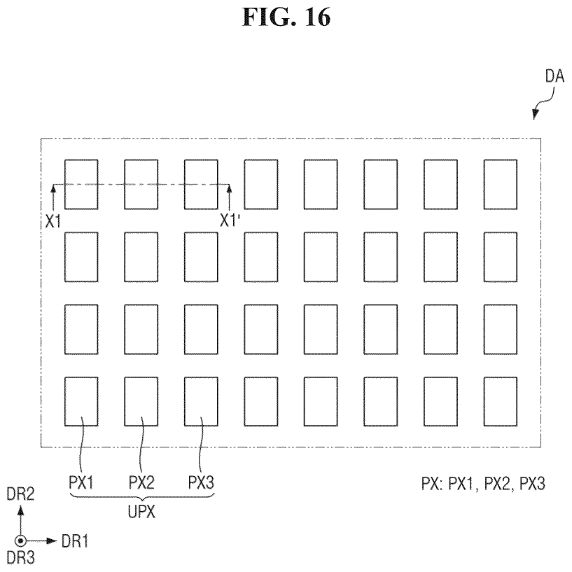

FIG. 16 is a schematic plan view illustrating a display area DA according to an embodiment. For example, FIG. 16 schematically illustrates pixels PX disposed in the display area DA of FIG. 14 or 15.

Referring to FIGS. 14 to 16, the display panel 100 may include pixels PX arranged in the display area DA. In an embodiment, the display panel 100 may include first pixels PX1 emitting light of a first color (e.g., first color sub-pixels), second pixels PX2 emitting light of a second color (e.g., second color sub-pixels), and third pixels PX3 emitting light of a third color (e.g., third color sub-pixels). In an embodiment, the first color may be red, the second color may be green, and the third color may be blue, but the disclosure is not limited thereto. At least one first pixel PX1, at least one second pixel PX2, and at least one third pixel PX3 adjacent to each other may constitute each unit pixel UPX. The number, type, and/or arrangement structure of the pixels PX constituting the unit pixel UPX may be variously changed depending on the embodiments.

Each pixel PX may include at least one light emitting element LE. For example, each pixel PX may include the light emitting element LE according to at least one of the embodiments described above. As an example, each pixel PX may include the light emitting element LE including the semiconductor layers EPI and the multi-film MLF surrounding the side surfaces of the semiconductor layers EPI, as illustrated in FIGS. 1 to 6.

The pixels PX may include light emitting elements LE that emit light of the same color, or may include light emitting elements LE that emit light of different colors. As an example, the first pixels PX1, the second pixels PX2, and the third pixels PX3 may include light emitting elements LE that emit light of the same color (e.g., blue light), and wavelength conversion patterns (e.g., wavelength conversion patterns including quantum dots) and/or color filters for converting or controlling the color of light emitted from the light emitting elements LE provided in each pixel PX may be disposed in light emitting areas of the first pixels PX1, the second pixels PX2, and/or the third pixels PX3. In other embodiments, the first pixels PX1, the second pixels PX2, and the third pixels PX3 may also include light emitting elements LE that emit light of a first color, light of a second color, and light of a third color, respectively. The pixels PX may include light emitting elements LE of substantially the same size, or may include light emitting elements LE of different sizes.

In an embodiment, the pixels PX may be arranged in the display area DA in a matrix form, a stripe form, or other forms. The sizes of the pixels PX (or the light emitting areas of the pixels PX) may be substantially the same or different from each other. The arrangement form, position, or size of the pixels PX may be variously changed depending on the embodiments.

In an embodiment, the pixels PX may have a quadrangular planar shape such as a rectangle or diamond, but the embodiments are not limited thereto. For example, the pixels PX may have a polygonal shape other than a quadrangular shape, a circular shape, an elliptical shape, or other planar shapes.

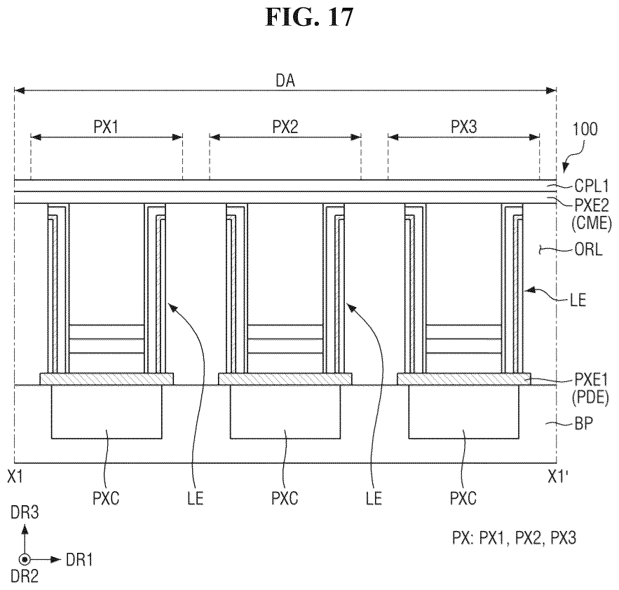

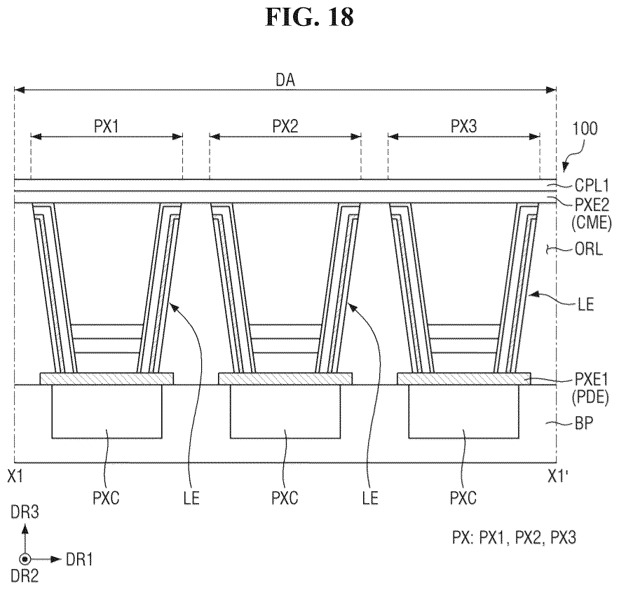

FIG. 17 is a schematic cross-section view illustrating a display panel 100 according to an embodiment. FIG. 18 is a schematic cross-section view illustrating a display panel 100 according to an embodiment. For example, FIGS. 17 and 18 illustrate different examples of a cross section of the display panel 100 corresponding to line X1-X1′ of FIG. 16, and illustrate schematic cross-sections of the first pixel PX1, the second pixel PX2, and the third pixel PX3 adjacent to each other in the first direction DR1. FIGS. 17 and 18 illustrate a display panel 100 including the light emitting element LE according to the embodiments of FIGS. 1 and 6, respectively, and other configurations may be substantially the same or similar.

FIGS. 17 and 18 illustrate embodiments in which the display device 10 are light emitting diode on silicon (LEDoS) in which light emitting diodes are disposed as light emitting elements LE on a semiconductor circuit board (e.g., a backplane substrate BP of the display panel 100 on which a pixel circuit PXC, etc. are formed based on a silicon wafer) formed through a semiconductor process using a silicon wafer. However, the device including the light emitting elements LE according to the embodiments is not limited thereto. For example, the light emitting elements LE fabricated according to the embodiments may be applied to display devices of different types and/or structures, or may be applied to devices of other types and/or structures, such as lighting devices.

Referring to FIGS. 17 and 18 in addition to FIGS. 1 to 16, the display panel 100 may include a backplane substrate BP (also referred to as a “display substrate”) and light emitting elements LE disposed on the backplane substrate BP. In addition, the display panel 100 may further include first electrodes PXE1 and a second electrode PXE2 connected to the light emitting elements LE, an organic film ORL disposed around the light emitting elements LE, and a first capping layer CPL1 covering the light emitting elements LE and the second electrode PXE2.

The backplane substrate BP may include a display area DA where pixels PX are arranged. In an embodiment, the backplane substrate BP may be a semiconductor circuit board formed through a semiconductor process using a silicon wafer. For example, the silicon wafer may be used as a base member to form the display panel 100. In an embodiment, the backplane substrate BP may include pixel circuits PXC provided in the display area DA.

The backplane substrate BP may further include the non-display area NDA illustrated in FIG. 14 or 15. In an embodiment, the backplane substrate BP may further include conductive patterns (e.g., common electrode connection portions), lines, and pads positioned in the non-display area NDA.

Each pixel PX may include a first electrode PXE1, a second electrode PXE2, and a light emitting element LE connected between the first electrode PXE1 and the second electrode PXE2. In an embodiment, each pixel PX may further include a pixel circuit PXC connected to the first electrode PXE1.

The pixel circuits PXC may be provided in the display area DA to correspond to an area where each pixel PX is formed. In an embodiment, each of the pixel circuits PXC may include a complementary metal-oxide semiconductor (CMOS) circuit formed on the backplane substrate BP using a semiconductor process. Each of the pixel circuits PXC may include at least one transistor. In addition, each of the pixel circuits PXC may include at least one capacitor.

The pixel circuit PXC of each pixel PX may be electrically connected to the first electrode PXE1 of the corresponding pixel PX. Each of the pixel circuits PXC may apply a first pixel voltage (e.g., a high potential pixel voltage) to the first electrode PXE1 connected thereto.

The first electrodes PXE1 of the pixels PX may be disposed on the backplane substrate BP. In an embodiment, the first electrodes PXE1 may be pad electrodes PDE (or bonding electrodes) connected to each light emitting element LE. The first electrodes PXE1 may be single-layer or multi-layer electrodes including at least one conductive material. In an embodiment, each first electrode PXE1 may connect the pixel circuit PXC of the corresponding pixel PX and the light emitting element LE.

At least one light emitting element LE may be disposed on the first electrode PXE1 of each pixel PX. The light emitting elements LE may be disposed or bonded onto each of the first electrodes PXE1. As an example, the light emitting element LE of each pixel PX may be disposed or bonded onto the first electrode PXE1 so that a contact electrode CTE is bonded to the first electrode PXE1 of the corresponding pixel PX. The light emitting element LE of each pixel PX may emit light by the voltage applied to the first electrode PXE1 and the second electrode PXE2 of the corresponding pixel PX.

Each light emitting element LE may include semiconductor layers EPI and a multi-film MLF surrounding the semiconductor layers EPI, as in the embodiments described with reference to FIGS. 1 to 6. As an example, as illustrated in FIGS. 1 to 6, each light emitting element LE may include semiconductor layers EPI including a first semiconductor layer SCL1, a light emitting layer EML, and a second semiconductor layer SCL2, a multi-insulating film MLO including a first insulating film INF1, a second insulating film INF2, and a third insulating film INF3 sequentially surrounding the side surfaces of the semiconductor layers EPI, a low refractive index film LRL surrounding the multi-insulating film MLO and having a thickness greater than the multi-insulating film MLO, and a reflective film RFL surrounding the low refractive index film LRL and including metal. In an embodiment, the light emitting element LE may further include a protective film PRL surrounding the reflective film RFL. In an embodiment, each light emitting element LE may further include a contact electrode CTE.

Each light emitting element LE may be disposed so that a surface (e.g., the second bottom surface S2 in FIG. 1 or FIG. 6) on which the contact electrode CTE (or the second semiconductor layer SCL2) is positioned faces the first electrode PXE1, and a surface (e.g., the first bottom surface S1 in FIG. 1 or FIG. 6) on which the first semiconductor layer SCL1 is positioned faces an upper portion where the second electrode PXE2 is positioned. In an embodiment, the first electrode PXE1 may be formed as a reflective electrode including a metal with high reflectivity, etc., and the second electrode PXE2 may be formed as a transparent or translucent electrode. Accordingly, the light generated from the light emitting elements LE may be emitted to the upper portion of the display panel 100 by transmitting through a surface (e.g., the first bottom surface S1) where the first semiconductor layer SCL1 is positioned and the second electrode PXE2. The arrangement direction of the light emitting elements LE or the direction of light emission from the light emitting elements LE and the display panel 100 may vary depending on the embodiments.

In an embodiment, the first pixel PX1, the second pixel PX2, and the third pixel PX3 may include light emitting elements LE that emit light of different colors. As an example, the light emitting element LE of the first pixel PX1, the light emitting element LE of the second pixel PX2, and the light emitting element LE of the third pixel PX3 may be a first color light emitting diode that emits light of a first color (e.g., a red light emitting diode), a second color light emitting diode that emits light of a second color (e.g., a green light emitting diode), and a third color light emitting diode that emits light of a third color (e.g., a blue light emitting diode), respectively.

In an embodiment, at least one insulating film may be disposed around the light emitting elements LE. As an example, an organic film ORL may be disposed around the light emitting elements LE. In an embodiment, the organic film ORL may be a filler filled between the light emitting elements LE. In an embodiment, the organic film ORL may be formed to have substantially the same height or a similar height to the light emitting elements LE, thereby reducing a step caused by the light emitting elements LE. The organic film ORL may include an organic insulating material. For example, the organic film ORL may include an acryl resin, an epoxy resin, a phenolic resin, a polyamide resin, a polyimide resin, or other organic insulating materials.

The second electrode PXE2 may be disposed on the light emitting elements LE. In an embodiment, the second electrode PXE2 of the pixels PX may be disposed on the light emitting elements LE and the organic film ORL and may be formed as one common electrode CME connected to each other, but is not limited thereto. In an embodiment, the second electrode PXE2 may be disposed on the light emitting elements LE to be electrically connected to the first semiconductor layers SCL1 of the light emitting elements LE.

The second electrode PXE2 may include a conductive material. In an embodiment, the second electrode PXE2 may be transparent or semi-transparent. Accordingly, the light generated from the light emitting elements LE may transmit through the second electrode PXE2 and be emitted to the upper portion of the pixels PX.

The first capping layer CPL1 may be disposed on the second electrode PXE2. The first capping layer CPL1 may be entirely disposed on at least the display area DA, and may entirely cover the first electrodes PXE1, the light emitting elements LE, the organic film ORL, and the second electrode PXE2 disposed on the backplane substrate BP. In an embodiment, the first capping layer CPL1 may be an inorganic insulating film including at least one inorganic insulating material suitable for blocking moisture permeation. As an example, the first capping layer CPL1 may include silicon oxide, silicon nitride, aluminum oxide, titanium oxide, or other inorganic insulating materials.

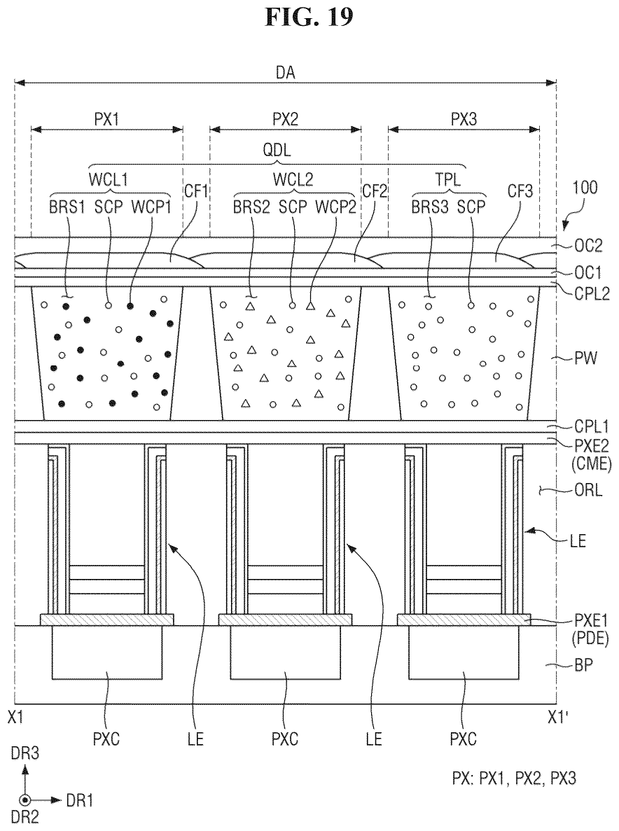

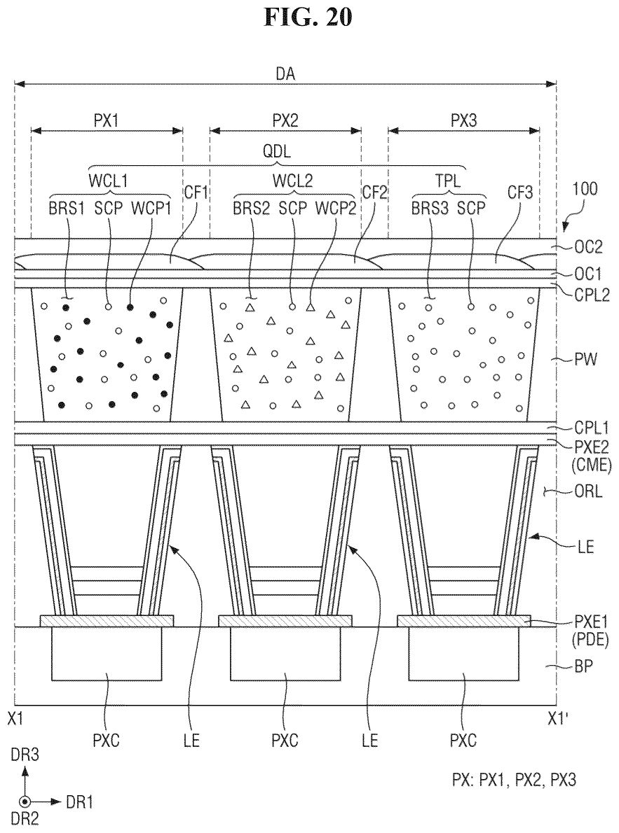

FIG. 19 is a schematic cross-section view illustrating a display panel 100 according to an embodiment. FIG. 20 is a schematic cross-section view illustrating a display panel 100 according to an embodiment. For example, FIGS. 19 and 20 illustrate examples of a cross section of the display panel 100 corresponding to line X1-X1′ of FIG. 16, and illustrate schematic cross-sections of the first pixel PX1, the second pixel PX2, and the third pixel PX3 adjacent to each other in the first direction DR1. Compared to the embodiments of FIGS. 17 and 18, the display panel 100 according to the embodiments of FIGS. 19 and 20 further includes additional configurations disposed on the first capping layer CPL1.

Referring to FIGS. 19 and 20 in addition to FIGS. 1 to 18, the display panel 100 may further include a wavelength conversion layer QDL and color filters. For example, the display panel 100 may further include a wavelength conversion layer QDL and a partition wall PW disposed on the first capping layer CPL1, a second capping layer CPL2 disposed on the wavelength conversion layer QDL and the partition wall PW, a first overcoat layer OC1 disposed on the second capping layer CPL2, color filters (e.g., a first color filter CF1, a second color filter CF2, and a third color filter CF3) disposed on the first overcoat layer OC1, and a second overcoat layer OC2.

The partition wall PW may partition or define light emitting areas where the wavelength conversion layer QDL is provided. For example, the partition wall PW may include openings corresponding to the light emitting areas of the pixels PX and may surround the light emitting areas.

In an embodiment, the partition wall PW may be formed to be relatively thick to provide a space in which the wavelength conversion layer QDL is formed. For example, the thickness of the partition wall PW may be in a range of approximately 1 μm to approximately 10 μm, respectively. In an embodiment, the partition wall PW may include an organic insulating material (e.g., epoxy resin, acrylic resin, cardo resin, imide resin, or other organic insulating materials). In an embodiment, the partition wall PW may further include a light blocking material. As an example, the partition wall PW may include a dye or pigment having light blocking properties.

The wavelength conversion layer QDL may be disposed in the light emitting areas of the pixels PX partitioned by the partition wall PW. The wavelength conversion layer QDL may convert light of a specific color emitted from the light emitting element LE of each pixel PX into light of another color, or may transmit light of a specific color emitted from the light emitting element LE without converting the light into light of another color.

In an embodiment, the wavelength conversion layer QDL may include a first wavelength conversion pattern WCL1 provided to the first pixel PX1, a second wavelength conversion pattern WCL2 provided to the second pixel PX2, and a light transmission pattern TPL provided to the third pixel PX3. The first wavelength conversion pattern WCL1, the second wavelength conversion pattern WCL2, and the light transmission pattern TPL may be disposed over the light emitting elements LE to overlap the light emitting element LE of the first pixel PX1, the light emitting element LE of the second pixel PX2, and the light emitting element LE of the third pixel PX3, respectively.

The first wavelength conversion pattern WCL1 may convert light of a specific color (e.g., blue light) emitted from the light emitting element LE of the first pixel PX1 into light of a first color (e.g., red light). The light of the first color converted by the first wavelength conversion pattern WCL1 may transmit through the first color filter CF1 and the like and be emitted to the outside of the first pixel PX1 (e.g., to the upper portion of the display panel 100).

The first wavelength conversion pattern WCL1 may include a first base resin BRS1 and first wavelength conversion particles WCP1. In an embodiment, the first wavelength conversion pattern WCL1 may further include scatterers SCP.

The first base resin BRS1 may include a light-transmitting organic material. As an example, the first base resin BRS1 may include an epoxy resin, an acrylic resin, a cardo resin, an imide resin, or the like.

The first wavelength conversion particles WCP1 may convert light emitted from the light emitting element LE of the first pixel PX1 into light of a first color (e.g., red light). In an embodiment, the first wavelength conversion particle WCP1 may be a quantum dot (e.g., a red quantum dot), a quantum rod, a fluorescent material, or a phosphorescent material, but is not limited thereto.

The scatterers SCP provided in the first wavelength conversion pattern WCL1 may scatter the light emitted from the light emitting element LE of the first pixel PX1 in a random direction. The scatterers SCP may have a refractive index different from that of the first base resin BRS1 and form an optical interface with the first base resin BRS1. For example, the scatterers SCP may be light scattering particles. In an embodiment, the scatterers SCP may be metal oxide particles or organic particles, but are not limited thereto.

The second wavelength conversion pattern WCL2 may convert light of a specific color (e.g., blue light) emitted from the light emitting element LE of the second pixel PX2 into light of a second color (e.g., green light). The light of the second color converted by the second wavelength conversion pattern WCL2 may transmit through the second color filter CF2 and the like and be emitted to the outside of the second pixel PX2 (e.g., to the upper portion of the display panel 100).

The second wavelength conversion pattern WCL2 may include a second base resin BRS2 and second wavelength conversion particles WCP2. In an embodiment, the second wavelength conversion pattern WCL2 may further include scatterers SCP.

The second base resin BRS2 may include a light-transmitting organic material. As an example, the second base resin BRS2 may include an epoxy resin, an acrylic resin, a cardo resin, an imide resin, or the like. In an embodiment, the second base resin BRS2 may include the same material as the first base resin BRS1, but is not limited thereto.

The second wavelength conversion particles WCP2 may convert light emitted from the light emitting element LE of the second pixel PX2 into light of a second color (e.g., green light). In an embodiment, the second wavelength conversion particle WCP2 may be a quantum dot (e.g., a green quantum dot), a quantum rod, a fluorescent material, or a phosphorescent material, but is not limited thereto.

The scatterers SCP provided in the second wavelength conversion pattern WCL2 may scatter the light emitted from the light emitting element LE of the second pixel PX2 in a random direction. The scatterers SCP may have a refractive index different from that of the second base resin BRS2 and form an optical interface with the second base resin BRS2. For example, the scatterers SCP may be light scattering particles. In an embodiment, the scatterers SCP may be metal oxide particles or organic particles, but are not limited thereto.

The light transmission pattern TPL may transmit incident light. For example, the light transmission pattern TPL may directly transmit light (e.g., blue light) emitted from the light emitting element LE of the third pixel PX3. The light transmission pattern TPL may include a third base resin BRS3 and scatterers SCP dispersed in the third base resin BRS3.

The third base resin BRS3 may include a light-transmitting organic material. As an example, the third base resin BRS3 may include an epoxy resin, an acrylic resin, a cardo resin, an imide resin, or the like. In an embodiment, the third base resin BRS3 may include the same material as at least one of the first base resin BRS1 and the second base resin BRS2, but is not limited thereto.

The scatterers SCP provided in the light transmission pattern TPL may scatter the light emitted from the light emitting element LE of the third pixel PX3 in a random direction. The scatterers SCP may have a refractive index different from that of the third base resin BRS3 and form an optical interface with the third base resin BRS3. For example, the scatterers SCP may be light scattering particles. In an embodiment, the scatterers SCP may be metal oxide particles or organic particles, but are not limited thereto. In an embodiment, the scatterers SCP provided in the first wavelength conversion pattern WCL1, the second wavelength conversion pattern WCL2, and the light transmission pattern TPL may be particles of the same material or type, but are not limited thereto.

A second capping layer CPL2 may be disposed on the wavelength conversion layer QDL and the partition wall PW. The second capping layer CPL2 may cover the wavelength conversion layer QDL and the partition wall PW and may protect the wavelength conversion layer QDL and the partition wall PW from moisture or foreign substances. In an embodiment, the second capping layer CPL2 may include at least one inorganic insulating material. In an embodiment, the second capping layer CPL2 may include the same material as the first capping layer CPL1, but is not limited thereto.

In an embodiment, the first overcoat layer OC1 may be disposed on the second capping layer CPL2. The first overcoat layer OC1 may be entirely disposed on the display area DA and may have a flat surface. In an embodiment, the first overcoat layer OC1 may include a light-transmitting organic material. For example, the first overcoat layer OC1 may include an epoxy resin, an acrylic resin, a cardo resin, an imide resin, or the like.

Color filters may be disposed on the first overcoat layer OC1. For example, a first color filter CF1, a second color filter CF2, and a third color filter CF3 may be disposed on the first overcoat layer OC1.

The first color filter CF1 may be provided to the first pixel PX1 to overlap the light emitting element LE and/or the first wavelength conversion pattern WCL1 of the first pixel PX1. The second color filter CF2 may be provided to the second pixel PX2 to overlap the light emitting element LE and/or the second wavelength conversion pattern WCL2 of the second pixel PX2. The third color filter CF3 may be provided to the third pixel PX3 to overlap the light emitting element LE and/or the third wavelength conversion pattern WCL3 of the third pixel PX3.

The first color filter CF1, the second color filter CF2, and the third color filter CF3 may selectively transmit light corresponding to the color or wavelength band to be emitted from each pixel PX, and may absorb light of different colors or different wavelength bands. For example, the first color filter CF1, the second color filter CF2, and the third color filter CF3 may selectively transmit light of a first color, light of a second color, and light of a third color, respectively, and may absorb light of different colors. In an embodiment, the first color filter CF1, the second color filter CF2, and the third color filter CF3 may be a red color filter, a green color filter, and a blue color filter, respectively, but are not limited thereto.

A second overcoat layer OC2 may be disposed on the color filters. The second overcoat layer OC2 may be entirely disposed on the display area DA and may have a flat surface. In an embodiment, the second overcoat layer OC2 may include a light-transmitting organic material. For example, the second overcoat layer OC2 may include an epoxy resin, an acrylic resin, a cardo resin, an imide resin, or the like. In an embodiment, the second overcoat layer OC2 may include the same material as the first overcoat layer OC1, but is not limited thereto.

The display device 10 according to the embodiments of FIGS. 14 to 20 may include a pixel PX including the light emitting element LE according to at least one of the embodiments of FIGS. 1 to 6 (or the light emitting element LE fabricated according to the embodiment of FIGS. 7 to 13). As a result, the reliability and light emission efficiency of the pixel PX and the display device 10 including the pixel PX may be improved.

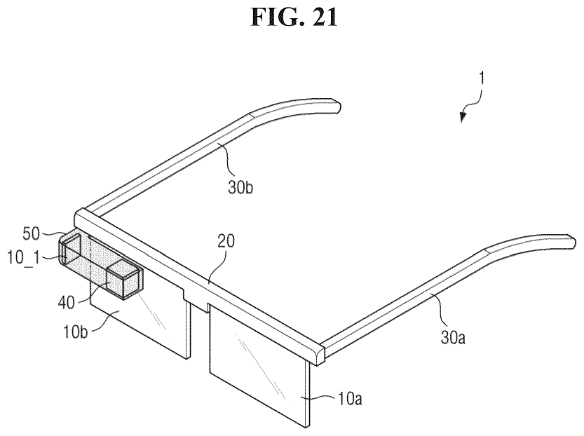

FIG. 21 is a schematic view illustrating a virtual reality device 1 including a display device 10_1 according to an embodiment.

Referring to FIG. 21, a virtual reality device 1 according to an embodiment may be a glasses-type device. The virtual reality device 1 according to an embodiment may include a display device 10_1, a left eye lens 10a, a right eye lens 10b, a support frame 20, eyeglass frames legs 30a and 30b, a reflective member 40, and a display device accommodating portion 50.

FIG. 21 illustrates the virtual reality device 1 including the eyeglass frame legs 30a and 30b, but the virtual reality device 1 according to an embodiment may also be applied to a head mounted display including a head mounted band that may be mounted on a head instead of the eyeglass frame legs 30a and 30b. For example, the virtual reality device 1 according to an embodiment is not limited to the form illustrated in FIG. 21, and may be applied in various forms to various other electronic devices.

The display device accommodating portion 50 may include a display device 10_1 and a reflective member 40. An image displayed on the display device 10_1 may be reflected by the reflective member 40 and provided to a user's right eye through the right eye lens 10b. Accordingly, the user may view a virtual reality image displayed on the display device 10_1 through the right eye.

FIG. 21 illustrates that the display device accommodating portion 50 is disposed at a right distal end of the support frame 20, but embodiments are not limited thereto. For example, the display device accommodating portion 50 may be disposed at a left distal end of the support frame 20. The image displayed on the display device 10_1 may be reflected by the reflective member 40 and provided to a user's left eye through the left eye lens 10a. Accordingly, the user may view a virtual reality image displayed on the display device 10_1 through the left eye. In other embodiments, the display device accommodating portion 50 may be disposed at both the left and right distal ends of the support frame 20. The user may view a virtual reality image displayed on the display device 10_1 through both the left and right eyes.

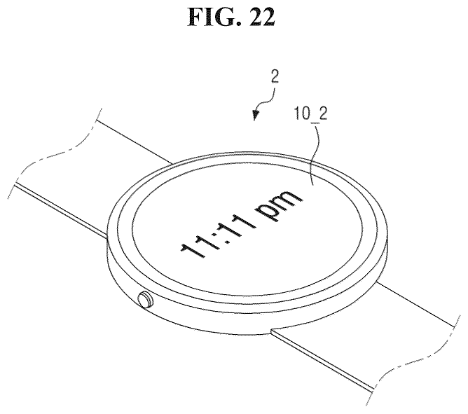

FIG. 22 is a schematic view illustrating a smart device including a display device 10_2 according to an embodiment.

Referring to FIG. 22, a display device 10_2 according to an embodiment may be applied to a smart watch 2, which is one of the smart devices. A planar shape of a clock display portion of the smart watch 2 may follow a planar shape of the display device 10_2. For example, in case that the display device 10_2 according to an embodiment has a circular or elliptical planar shape, the clock display portion of the smart watch 2 may have a circular or elliptical planar shape. In other embodiments, in case that the display device 10_2 according to an embodiment has a quadrangular planar shape, the clock display portion of the smart watch 2 may have a quadrangular planar shape. However, the embodiments are not limited thereto, and the clock display portion of the smart watch 2 may not follow the planar shape of the display device 10_2.

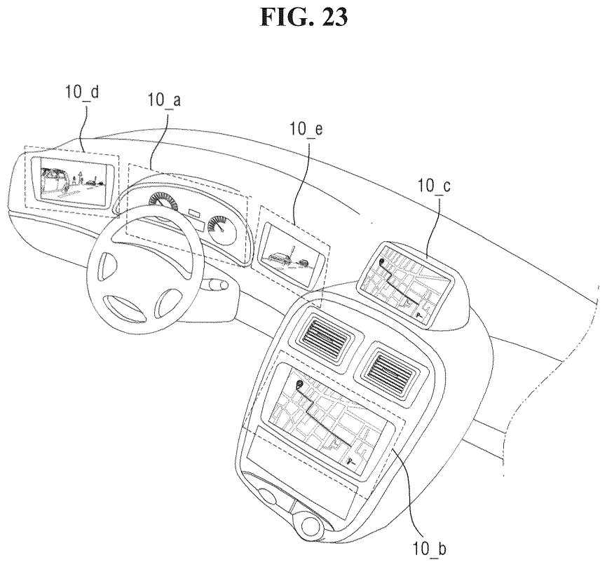

FIG. 23 is a schematic view illustrating an instrument board and a center fascia of a vehicle including display devices 10_a, 10_b, 10_c, 10_d, and 10_e according to an embodiment. A vehicle to which display devices 10_a, 10_b, 10_c, 10_d, and 10_e according to an embodiment may be applied is illustrated in FIG. 23.

Referring to FIG. 23, the display devices 10_a, 10_b, and 10_c according to an embodiment may be applied to an instrument board of the vehicle, applied to a center fascia of the vehicle, or applied to a center information display (CID) disposed on a dashboard of the vehicle. In other embodiments, the display devices 10_d and 10_e according to an embodiment may be applied to a room mirror display substituting for a side mirror of the vehicle.

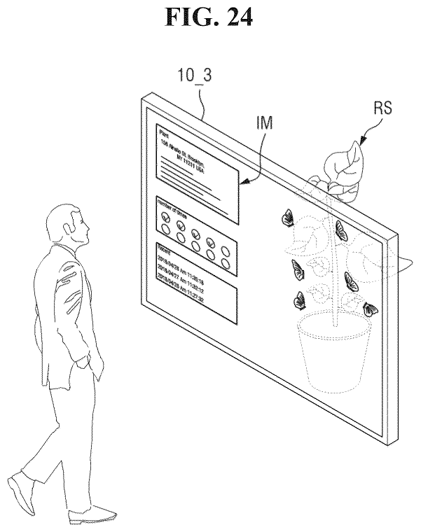

FIG. 24 is a schematic view illustrating a transparent display device including a display device 10_3 according to an embodiment.

Referring to FIG. 24, a display device 10_3 according to an embodiment may be applied to a transparent display device. The transparent display device may transmit light while displaying an image IM. Accordingly, a user positioned in front of the transparent display device may not only view the image IM displayed on the display device 10_3, but also view an object RS or background positioned behind the transparent display device. In case the display device 10_3 is applied to the transparent display device, the display panel 100 may include a light-transmitting portion capable of transmitting light or may be formed on a substrate member made of a material capable of transmitting light.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A light emitting element comprising:
semiconductor layers including:
a first semiconductor layer;
a light emitting layer; and
a second semiconductor layer,
a multi-insulating film including a first insulating film, a second insulating film, and a third insulating film sequentially surrounding side surfaces of the semiconductor layers;
a low refractive index film surrounding the multi-insulating film and having a thickness greater than a thickness of the multi-insulating film; and
a reflective film surrounding the low refractive index film and including metal.

2. The light emitting element of claim 1, wherein the first insulating film includes a material having dissociation energy in a range of about 7 eV to about 9 eV.

3. The light emitting element of claim 1, wherein the first insulating film includes at least one of ZrO₂, SiO₂, HfO₂, Ta₂O₅, and La₂O₃.

4. The light emitting element of claim 1, wherein
each of the first insulating film and the third insulating film includes at least one of ZrO₂ and HfO₂, and
the second insulating film includes at least one of Al₂O₃ and SiO₂.

5. The light emitting element of claim 1, wherein
the first insulating film, the second insulating film, and the third insulating film include M1O₂ type oxide, M2₂O₃ type oxide, and M3O₂ type oxide, respectively, and
M1, M2 and M3 are each metal material.

6. The light emitting element of claim 5, wherein
each of the first insulating film and the third insulating film includes at least one of ZrO₂, SiO₂, HfO₂, GeO₂, TiO₂, and TeO₂, and
the second insulating film includes at least one of Al₂O₃, Y₂O₃, La₂O₃, Ce₂O₃, Lu₂O₃, Sc₂O₃, and Yb₂O₃.

7. The light emitting element of claim 1, wherein the first insulating film, the second insulating film, and the third insulating film each have a thickness in a range of about 0.5 nm to about 5 nm.

8. The light emitting element of claim 1, wherein a sum of thicknesses of the first insulating film, the second insulating film, and the third insulating film is about 10 nm or less.

9. The light emitting element of claim 1, wherein
the multi-insulating film and the low refractive index film constitute a multi-composite film between the semiconductor layers and the reflective film,
a thickness of the multi-composite film satisfies the range of Equation 1:
$$\frac{λ}{4 n} \times 0.8 \leq t \leq \frac{λ}{4 n} \times 1.2 , \qquad [ Equation 1 ]$$
in Equation 1, t is the thickness of the multi-composite film, λ is a light emitting wavelength of the light emitting layer, and n is a composite refractive index of the multi-composite film.

10. The light emitting element of claim 1, wherein the low refractive index film includes SiO₂.

11. The light emitting element of claim 1, wherein the reflective film includes at least one of aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), and chromium (Cr).

12. The light emitting element of claim 1, wherein the reflective film has a thickness in a range of about 30 nm to about 200 nm.

13. The light emitting element of claim 1, wherein the semiconductor layers have a width in a range of about 0.5 μm to about 10 μm.

14. The light emitting element of claim 1, further comprising:
a protective film surrounding the reflective film.

15. The light emitting element of claim 14, further comprising:
a contact electrode disposed on the semiconductor layers,
wherein the multi-insulating film, the low refractive index film, the reflective film, and the protective film further surround a side surface of the contact electrode.

16. The light emitting element of claim 1, wherein the side surfaces of the semiconductor layers have an inclined surface inclined with respect to a first bottom surface of the semiconductor layers.

17. A display device comprising:
a first electrode;
a second electrode; and
a light emitting element electrically connected between the first electrode and the second electrode, wherein the light emitting element includes:
semiconductor layers including:
a first semiconductor layer;
a light emitting layer; and
a second semiconductor layer,
a multi-insulating film including a first insulating film, a second insulating film, and a third insulating film sequentially surrounding side surfaces of the semiconductor layers;
a low refractive index film surrounding the multi-insulating film and having a thickness greater than a thickness of the multi-insulating film; and
a reflective film surrounding the low refractive index film and including metal.

18. The display device of claim 17, wherein the light emitting element further includes a protective film surrounding the reflective film.

19. A method of fabricating a light emitting element, the method comprising:
sequentially forming a first semiconductor layer, a light emitting layer, and a second semiconductor layer on a substrate;
etching the first semiconductor layer, the light emitting layer, and the second semiconductor layer;
sequentially forming a multi-insulating film including a first insulating film, a second insulating film, and a third insulating film, a low refractive index film having a thickness greater than a thickness of the multi-insulating film, and a reflective film including a metal, on the substrate, the first semiconductor layer, the light emitting layer, and the second semiconductor layer; and
forming a multi-film surrounding side surfaces of the first semiconductor layer, the light emitting layer, and the second semiconductor layer by etching the multi-insulating film, the low refractive index film and the reflective film.

20. The method of claim 19, further comprising:
forming a protective film on the reflective film prior to etching the multi-insulating film, the low refractive index film, and the reflective film,
wherein the multi-film is formed of at least six films including the multi-insulating film, the low refractive index film, the reflective film, and the protective film.
